(19) United States
(12) Patent Application Publication
(10) Pub. No.: US 2026/0019053 A1
(43) Pub. Date: Jan. 15, 2026

(54) RF ANALOG FRONT END

(71) Applicant: Texas Instruments Incorporated, Dallas, TX (US)

(72) Inventors: Sharanaprasad Melkundi, Bangalore (IN); Shagun Dusad, Bangalore (IN); Visvesvaraya Appala Pentakota, Bangalore (IN); Jagannathan Venkataraman, Bangalore (IN); Krishna Kant Ahir, Bangalore (IN)

(21) Appl. No.: 19/222,710

(22) Filed: May 29, 2025

(30) Foreign Application Priority Data
Jul. 12, 2024 (IN) 202441053403

(51) Int. Cl. H03F 3/45; H03F 1/02; H04B 1/00; H04B 1/40

(52) U.S. Cl. CPC H03F 3/45641; H03F 1/0261; H03F 3/45264; H04B 1/0067; H04B 1/40; H03F 2200/294; H03F 2200/451

(57) ABSTRACT

In an embodiment, an electronic circuit includes: an amplifier having first and second outputs, first and second inputs, and first and second terminals; a high pass filter coupled between the first and second terminals of the amplifier; and a configurable output network coupled between the first and second outputs of the amplifier.

### CROSS-REFERENCE TO RELATED APPLICATION

This patent application claims the benefit of and priority to Indian Provisional Patent Application No. 202441053403, filed Jul. 12, 2024, which Application is hereby incorporated herein by reference in its entirety.

### TECHNICAL FIELD

The present disclosure relates generally to an electronic system and method, and, in particular embodiments, to a radio-frequency (RF) analog front end.

### BACKGROUND

In electronics, an analog-to-digital converter (ADC) is a circuit that converts an analog signal into a digital signal. A digital-to-analog converter (DAC) is a circuit that converts a digital signal to an analog signal. ADCs and DACs are utilized in a variety of applications such as audio, video, control, instrumentation, data acquisition, communication, imaging, automotive, and aerospace applications, among other applications. In communication applications, for example, ADCs are utilized to convert analog radio frequency (RF) signals received over a wired or wireless communication medium into digital signals for further processing. There are many architectures according to which an ADC can be implemented depending on the application in which the ADC is utilized. For example, the suitability of an ADC architecture for a particular application is determined according to performance characteristics such as bandwidth and signal-to-noise and distortion ratio (SNDR), among others.

### SUMMARY

In accordance to an embodiment, an electronic circuit includes: an amplifier having first and second outputs, first and second inputs, and first and second terminals; a high pass filter coupled between the first and second terminals of the amplifier; and a configurable output network coupled between the first and second outputs of the amplifier.

In accordance to an embodiment, an integrated circuit includes: a semiconductor substrate; a first metal layer disposed above the semiconductor substrate; a second metal layer disposed above the semiconductor substrate; a first switch having a first terminal and a second terminal; a first connector disposed in the first metal layer and coupled to the first terminal of the first switch; a second connector disposed in the first metal layer and coupled to the second terminal of the first switch, the first connector and the second connector arranged in a first shape; a second switch having a first terminal and a second terminal; a third connector disposed in the second metal layer and coupled to the first terminal of the second switch and the second terminal of the first switch; and a fourth connector disposed in the second metal layer and coupled to the second terminal of the second switch and the first terminal of the first switch, the third connector and the fourth connector arranged in a second shape concentric with and substantially aligned to the first shape.

In accordance to an embodiment, a method includes: causing, at a first time, a configurable output network of a digital signal attenuator (DSA) of a transceiver to operate in a first mode of operation; operating the DSA in the first mode of operation; causing, at a second time, the configurable output network of the DSA of the transceiver to operate in a second mode of operation; and operating the DSA in the second mode of operation.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a block diagram of an example radio frequency (RF) circuit;

FIG. 2 is a block diagram of an example receiver that can implement one or more of the receivers of FIG. 1;

FIG. 3 is a schematic diagram of an example implementation of the digital signal attenuator (DSA) of FIG. 2;

FIG. 4 is a schematic diagram of the DSA of FIG. 3 when structured in a bandpass (e.g., narrow) mode of operation;

FIG. 5 is a schematic diagram of the DSA of FIG. 3 when structured in a wideband mode of operation;

FIG. 6A is a schematic diagram of a first example inductor that can implement at least one of the inductors of FIG. 3;

FIG. 6B is a cross-sectional view illustrating how the switch is coupled to the connectors of the first metal layer of the semiconductor;

FIG. 7A is a schematic diagram of a second example inductor that can implement at least one of the inductors of FIG. 3;

FIG. 7B is a cross-sectional view illustrating how the switch is coupled to the connectors of the first metal layer of the semiconductor;

FIG. 7C is a cross-sectional view illustrating how the switch is coupled to the connectors of the second metal layer of the semiconductor; and

FIG. 8 illustrates a flowchart of embodiment method 800 for operating the DSA of FIG. 3, according to an embodiment of the present disclosure. DSA of FIG. 3.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Some embodiments relate generally to analog-to-digital converters and, more particularly, to methods and apparatus to attenuate signals for radio frequency sampling analog-to-digital converters.

Modern radio frequency (RF) applications include communication and radar applications. Other RF applications include motor control feedback, network and vector analyzers, communications test equipment, nondestructive testing, microwave receivers, software-defined radios, quadrature and diversity radio receivers, and handheld radio and instrumentation. In example communication applications, an RF circuit may be implemented in any of a macro remote radio unit (RRU), an active antenna system (AAS) for massive multiple-input multiple-output (MIMO) (mMIMO), a base station (small cell or large cell), a distributed antenna system (DAS), or a repeater, among others.

In modern applications, RF circuits operate in a variety of frequency ranges. Even within a particular application, operating frequencies of RF circuits can vary. For example, while RF circuits in communication applications generally operate between 20 kilohertz (kHz) and 300 gigahertz (GHz), RF circuits in satellite communication applications operate between 2 GHz and 30 GHz. Also, in multi-carrier, multi-mode cellular communication applications, RF circuits can support multiple bands, such as dual-band, tri-band, quad-band, etc., with center frequencies ranging from 800 MHz to 2.1 GHz. In smart antenna communication applications, RF circuits can support fourth generation (4G) communication (600 MHz-2.6 GHz), fifth generation (5G) communication (<1 GHz-40 GHz), and sixth generation (6G) communication (7 GHz-300 GHz).

In modern communication applications, service providers (also referred to as carriers) utilize upper frequency ranges (for example, 5G and 6G frequency ranges) to support larger data rates. Also, in modern communication applications, different carriers operate at a variety of center frequencies. For example, a first carrier communicates in a frequency band centered at a first center frequency and a second carrier communicates in a frequency band centered at a second center frequency. In some examples, a carrier supports multiple bands of operation at the same time.

To support operation in upper frequency ranges, use by various carriers operating at various center frequencies, and operation in multiple frequency bands, ADCs in RF circuits are to support a large bandwidth of input frequency. For example, an ADC can provide wideband support and narrowband support. Example wideband support includes supporting operating in a frequency band that ranges from 100 MHz to 6 GHz, or from 3.1 GHz to 10.6 GHz. Example narrowband support includes supporting a frequency band that is approximately 400 MHz wide with a center frequency anywhere from 1.8 GHz to 7.2 GHz. Wideband support by ADCs of an RF circuit allows the RF circuit to support scenarios where a carrier operates in multiple bands simultaneously. Also, providing wideband support by ADCs of an RF circuit allows the RF circuit to implement a feedback channel that can improve performance of the RF circuit. Narrowband support by ADCs of an RF circuit allows the RF circuit to achieve a better noise figure (for example, compared to wideband operation).

It may be beneficial to support both narrowband and wideband operations. For example, a device may support multiple protocols one or more of which may be narrowband (e.g., WiFi, BLE, etc.), and one or more of which may be wideband (e.g., UWB, etc.).

To support both wideband and narrowband operation, the input reflection coefficient (S11) parameter and input bandwidth of ADCs are to support frequencies up to 6 GHz. The S11 parameter and input bandwidth of an ADC may be dependent on a digital signal attenuator (DSA) of the ADC. For example, in a receiver, the DSA may be positioned between the matching network and the ADC. Thus, as the same matching network is to be used across frequency bands, the input capacitance of the DSA is to be low to maintain a low S11 parameter for the ADC.

In examples described herein, a DSA may be understood as a circuit that adjusts the magnitude of an input signal to an ADC to ensure that the magnitude is within a threshold range for the ADC (such as, within an operating voltage range of the ADC) regardless of the received signal strength of the input signal. For example, a DSA may have a variable gain to (1) amplify an analog signal received by a base station when the amplitude of the analog signal is small (for example, when the analog signal originates from a device that is far from the base station) and (2) attenuate an analog signal received by the base station when the amplitude of the analog signal is large (for example, when the analog signal originates from a device that is close to the base station).

DSAs can be programmable circuits, for example, to allow for tuning of the S11 parameter. Also, DSAs can be passive circuits or active circuits. For example, a passive DSA does not apply a positive gain to an input signal and attenuates input signals having magnitudes that exceed the threshold range to be within the threshold range. Also, for example, an active DSA applies a positive gain to input signals having magnitudes below the threshold range and attenuates input signals having magnitudes that exceed the threshold range to be within the threshold range.

Passive DSAs are useful, for example, in base stations supporting small cells (small areas of coverage) and support larger magnitude input signals than active DSAs. However, passive DSAs have large noise figures. A noise figure (NF) quantifies the degradation of the signal-to-noise ratio (SNR) caused by a component where lower value NFs indicate better performance. Active DSAs are useful, for example, in base stations supporting large cells (large areas of coverage). However, active DSAs do not include noise cancelling techniques, and, as a result of lowpass filtering at the output, introduce noise aliasing that increases the NFs of active DSAs. To mitigate amplified noise, active DSAs can be tuned. However, tuning active DSAs may be complicated and may require many components of the active DSAs to be adjusted.

In some embodiments, to support both wideband and narrowband operation, the S11 parameter and input bandwidth of ADCs is to support frequencies, e.g., up to 6 GHz and is dependent on a DSA of the ADC. However, DSAs may only support a narrow bandwidth of input frequency (for example, for a designated frequency band of a particular carrier). As such, a single fixed-design DSA may not be able to support multiple carriers or multiple bands. Advantageously, some embodiments described herein include a highly configurable DSA having (1) a reconfigurable output network supporting a bandpass (e.g., narrow) mode of operation and a wideband mode of operation, (2) cross-coupled transistors to improve the S11 parameter of an ADC coupled to the DSA across frequency, and (3) a high pass filter (HPF) to block frequency aliasing when the DSA is structured in the wideband mode of operation. In some embodiments, when structured in the narrow mode of operation, the reconfigurable output network achieves a lower NF and allows for a wide tuning range. For example, the reconfigurable output network may include tunable, area-efficient inductors that allow for the frequency band of a bandpass filter (BPF) implemented by the reconfigurable output network to be configured. In some embodiments, when structured in the wideband mode of operation, the reconfigurable output network supports operating in a frequency band ranging from 100 MHz to 6 GHz. Also, the reconfigurable output network may consume three to four times less arca on a chip than other approaches.

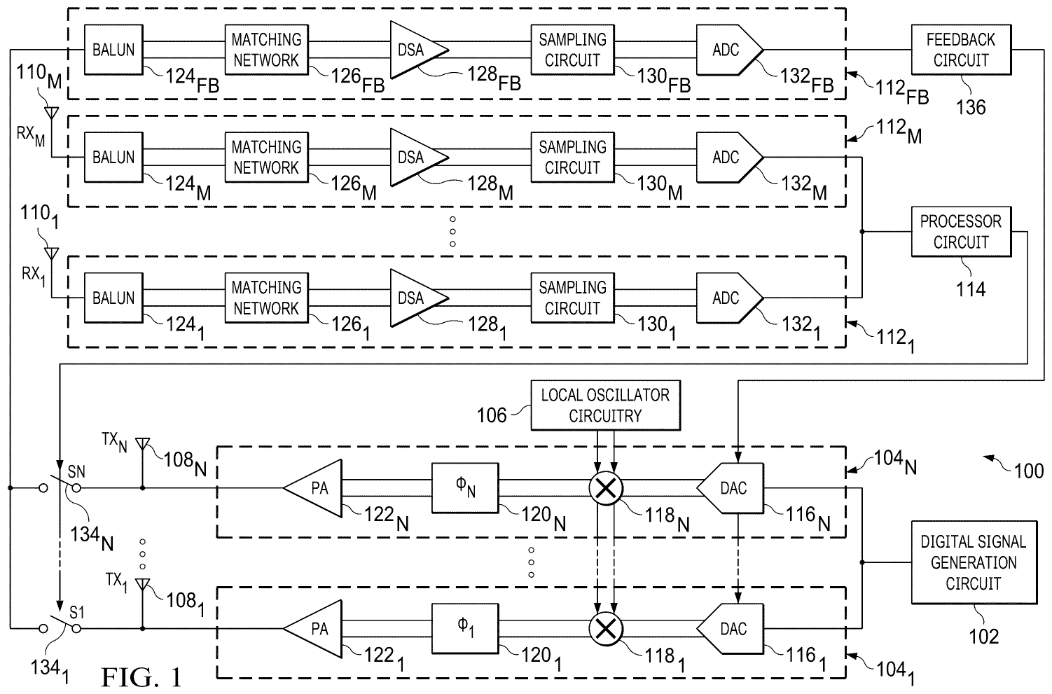

FIG. 1 is a block diagram of radio frequency (RF) circuit 100, according to an embodiment of the present disclosure. In the example of FIG. 1, the RF circuit 100 includes digital signal generation circuit 102, transmitters 104₁-104_{N}, local oscillator circuit 106, transmit antennas 108₁-108_{N}, receive antennas 110₁-110_{M}, receivers 112₁-112_{M}, and processor circuit 114. Also, in the example of FIG. 1, the transmitters 104₁-104_{N} include digital-to-analog converters (DACs) 116₁-116_{N}, mixers 118₁-118_{N}, phase shifters 120₁-120_{N}, and example power amplifiers (PAS) 122₁-122_{N}, respectively.

In some embodiments, circuit 100 may be implemented using a single IC that includes elements 102, 104, 106, 112, 114, and 136. In other embodiments, circuit 100 may be implemented using multiple discrete components, as opposed to being integrated in a single IC. Other implementations are also possible.

In some embodiments, digital signal generation circuit 102 is implemented as part of processor circuit 114. In other embodiments, digital signal generation circuit 102 is implemented separate from processor circuit 114.

In the illustrated example of FIG. 1, the receivers 112₁-112_{M} include balun circuits 124₁-124_{M}, matching networks 126₁-126_{M}, digital signal attenuators (DSAs) 128₁-128_{M}, sampling circuits 130₁-130_{M}, and analog-to-digital converters (ADCs) 132₁-132_{M}, respectively. In the example of FIG. 1, the RF circuit 100 includes feedback receiver 112_{FB}, example feedback switches 134₁-134_{N}, and feedback circuit 136. In the example of FIG. 1, the feedback receiver 112_{FB} includes balun circuit 124_{FB}, matching network 126_{FB}, DSA 128_{FB} sampling circuit 130_{FB}, and ADCs 132_{FB}.

In the illustrated example of FIG. 1, the RF circuit 100 includes sixteen of each of the transmitters 104₁-104_{N} and the transmit antennas 108₁-108_{N}. For example, N equals sixteen. In the example of FIG. 1, the RF circuit 100 includes one instance of the feedback receiver 112_{FB} for every four of the transmitters 104₁-104_{N}. Thus, for example, while one instance of the feedback receiver 112_{FB} is illustrated in FIG. 1, in some embodiments, the RF circuit 100 of FIG. 1 includes four instances of the feedback receiver 112_{FB}. In the example of FIG. 1, the RF circuit 100 includes sixteen of each of the receive antennas 110₁-110_{M} and the receivers 112₁-112_{M}. For example, M equals sixteen. In some examples, the RF circuit 100 includes a different number of any of the transmitters 104₁-104_{N}, the transmit antennas 108₁-108_{N}, the receive antennas 110₁-110_{M}, the feedback receiver 112_{FB}, or the receivers 112₁-112_{M}.

In some examples, the RF circuit 100 and the processor circuit 114 are implemented separately and may be coupled together. Also or alternatively, the RF circuit 100 is implemented with the processor circuit 114, for example, in a single chip package or on a system on chip (SoC) (for example, a single IC). In examples where the RF circuit 100 is implemented with the processor circuit 114 on a SoC, the RF circuit 100 may correspond to a sub-circuit of the IC that forms the SoC.

In the illustrated example of FIG. 1, each of the DACs 116₁-116_{N} has a first input, a second input, a first output, and a second output. In the example of FIG. 1, each of the balun circuits 124₁-124_{M} and the balun circuit 124_{FB} has an input, a first output, and a second output. Each of the PAs 122₁-122_{N}, each of the ADCs 132₁-132_{M}, and the ADC 132_{FB} of FIG. 1 has a first input, a second input, and an output. Also, in the example of FIG. 1, each of the phase shifters 120₁-120_{N}, each of the matching networks 126₁-126_{M}, the matching network 126_{FB}, each of the DSAs 128₁-128_{M}, the DSA 128_{FB}, each of the sampling circuits 130₁-130_{M}, and the sampling circuit 130_{FB} has a first input, a second input, a first output, and a second output.

In the illustrated example of FIG. 1, each of the mixers 118₁-118_{N} has a first input, a second input, a third input, a fourth input, a first output, and a second output. In the example of FIG. 1, the digital signal generation circuit 102 has an output. Each of the processor circuit 114 and the feedback circuit 136 of FIG. 1 has an input and an output. In the example of FIG. 1, the local oscillator circuit 106 has a first output and a second output. Also, each of the feedback switches 134₁-134_{N} has a control terminal, a first current path terminal, and a second current path terminal.

In the illustrated example of FIG. 1, the digital signal generation circuit 102 is implemented by at least one of analog circuitry or digital circuitry. In the example of FIG. 1, the digital signal generation circuit 102 is coupled to the transmitters 104₁-104_{N}. For example, the output of the digital signal generation circuit 102 is coupled to respective first inputs of the DACs 116₁-116_{N} of the transmitters 104₁-104_{N}. In some examples, the digital signal generation circuit 102 is coupled to the processor circuit 114.

In the illustrated example of FIG. 1, each of the DACs 116₁-116_{N} is implemented by at least one of analog circuitry or digital circuitry. In the example of FIG. 1, the DACs 116₁-116_{N} are coupled to the digital signal generation circuit 102. For example, the first input of respective DACs is coupled to the output of the digital signal generation circuit 102. In the example of FIG. 1, the DACs 116₁-116_{N} are coupled to the processor circuit 114. For example, the second input of respective DACs is coupled to the output of the feedback circuit 136. Also, in the example of FIG. 1, the DACs 116₁-116_{N} are coupled to the mixers 118₁-118_{N}. For example, the first output and the second output of respective DACs are coupled to the first input and the second input of respective mixers, respectively.

In the illustrated example of FIG. 1, each of the mixers 118₁-118_{N} is implemented by at least one of analog circuitry or digital circuitry. In the example of FIG. 1, the mixers 118₁-118_{N} are coupled to the DACs 116₁-116_{N}. For example, the first input and the second input of respective mixers are coupled to the first output and the second output of respective DACs, respectively. Also, in the example of FIG. 1, the mixers 118₁-118_{N} are coupled to the local oscillator circuit 106. For example, the third input and the fourth input of respective mixers are coupled to the first output and the second output of the local oscillator circuit 106, respectively. In the example of FIG. 1, the mixers 118₁-118_{N} are coupled to the phase shifters 120₁-120_{N}. For example, the first output and the second output of respective mixers are coupled to the first input and the second input of respective phase shifters, respectively.

In the illustrated example of FIG. 1, the local oscillator circuit 106 is implemented by at least one of analog circuitry or digital circuitry. For example, the local oscillator circuit 106 includes a phase locked loop (PLL) oscillator with a voltage-controlled oscillator (VCO). In additional or alternative examples, the local oscillator circuit 106 includes a crystal oscillator. In the example of FIG. 1, the local oscillator circuit 106 is coupled to the mixers 118₁-118_{N}. For example, the first output and the second output of the local oscillator circuit 106 are coupled to the third input and the fourth input of respective ones of the mixers 118₁-118_{N}, respectively.

In the illustrated example of FIG. 1, each of the phase shifters 120₁-120_{N} is implemented by at least one of analog circuitry or digital circuitry. In the example of FIG. 1, the phase shifters 120₁-120_{N} are coupled to the mixers 118₁-118_{N}. For example, the first input and the second input of respective phase shifters are coupled to the first output and the second output of respective mixers, respectively. Also, in the example of FIG. 1, the phase shifters 120₁-120_{N} are coupled to the PAs 122₁-122_{N}. For example, the first output and the second output of respective phase shifters are coupled to the first input and the second input of respective PAs, respectively.

In the illustrated example of FIG. 1, each of the PAs 122₁-122_{N} is implemented by at least one of analog circuitry or digital circuitry. In the example of FIG. 1, the PAs 122₁-122_{N} are coupled to the phase shifters 120₁-120_{N}. For example, the first input and the second input of respective PAs are coupled to the first output and the second output of respective phase shifters, respectively. Also, in the example of FIG. 1, the PAs 122₁-122_{N} are coupled to the transmit antennas 108₁-108_{N}. For example, the output of respective PAs is coupled to respective transmit antennas. In the example of FIG. 1, the PAs 122₁-122_{N} are coupled to the feedback switches 134₁-134_{N}. For example, the output of respective PAs is coupled to the first current path terminals of respective feedback switches.

In the illustrated example of FIG. 1, the digital signal generation circuit 102 includes functionality to receive signal parameter values (for example, from the processor circuit 114) for a signal (for example, a data signal to be modulated on a carrier signal, a sequence of chirps in a radar frame, etc.). In some examples, the signal parameters are defined by a system architecture and may include, for example, a transmitter enable parameter for indicating which of the transmitters 104₁-104_{N} to enable, a frequency value for the signal, an ADC sampling time, and a transmitter start time, among others. In the example of FIG. 1, the digital signal generation circuit 102 also includes functionality to generate signals (for example, a data signal to be modulated on a carrier signal, a chirp, etc.) for transmission responsive to the signal parameter values (for example, received from the processor circuit 114). For example, the digital signal generation circuit 102 generates signals for an application in which the RF circuit 100 is implemented (for example, a communication application, a radar application, etc.). Example applications in which the RF circuit 100 may be implemented include ultra-wideband (UWB) applications, Wi-Fi applications, Bluetooth® low energy (BLE) applications, sub-1 GHz applications, and applications based on an Institute of Electrical and Electronics Engineers (IEEE) standard such as IEEE 802.15.4.

In the illustrated example of FIG. 1, each of the DACs 116₁-116_{N} sample signals generated by the digital signal generation circuit 102. In the example of FIG. 1, the local oscillator circuit 106 generates a carrier signal onto which a data signal (for example, generated by the digital signal generation circuit 102) is to be modulated. Also, in the example of FIG. 1, the mixers 118₁-118_{N} mix the local oscillator (LO) signal with the data signal sampled by each of the DACs 116₁-116_{N}. As such, each of the mixers 118₁-118_{N} generates a modulated signal.

In the illustrated example of FIG. 1, each of the phase shifters 120₁-120_{N} receives a modulated signal provided by respective ones of the mixers 118₁-118_{N} and applies a phase shift to the modulated signal for an application in which the RF circuit 100 is utilized. In the example of FIG. 1, each of the phase shifters 122₁-122_{N} amplifies a modulated (and possibly phase shifted) signal received from respective ones of the phase shifters 120₁-120_{N} and provides the amplified signal to respective ones of the transmit antennas 108₁-108_{N}. Also, in the example of FIG. 1, the transmitters 104₁-104_{N} transmit the amplified signals via the transmit antennas 108₁-108_{N}.

In the illustrated example FIG. 1, each of the balun circuits 124₁-124_{M} is implemented by at least one of analog circuitry or digital circuitry. In the example of FIG. 1, the balun circuits 124₁-124_{M} are coupled to the receive antennas 110₁-110_{M}. For example, the input of respective balun circuits is coupled to respective ones of the receive antennas 110₁-110_{M}. Also, in the example of FIG. 1, the balun circuits 124₁-124_{M} are coupled to the matching networks 126₁-126_{M}. For example, the first output and the second output of respective balun circuits are coupled to the first input and the second input of respective matching networks, respectively.

In the illustrated example of FIG. 1, each of the matching networks 126₁-126_{M} is implemented by at least one of analog circuitry or digital circuitry. In the example of FIG. 1, the matching networks 126₁-126_{M} are coupled to the balun circuits 124₁-124_{M}. For example, the first input and the second input of respective matching networks are coupled to the first output and the second output of respective balun circuits, respectively. Also, the matching networks 126₁-126_{M} are coupled to the DSAs 128₁-128_{M}. For example, the first output and the second output of respective matching networks are coupled to the first input and the second input of respective DSAs 128₁-128_{M}.

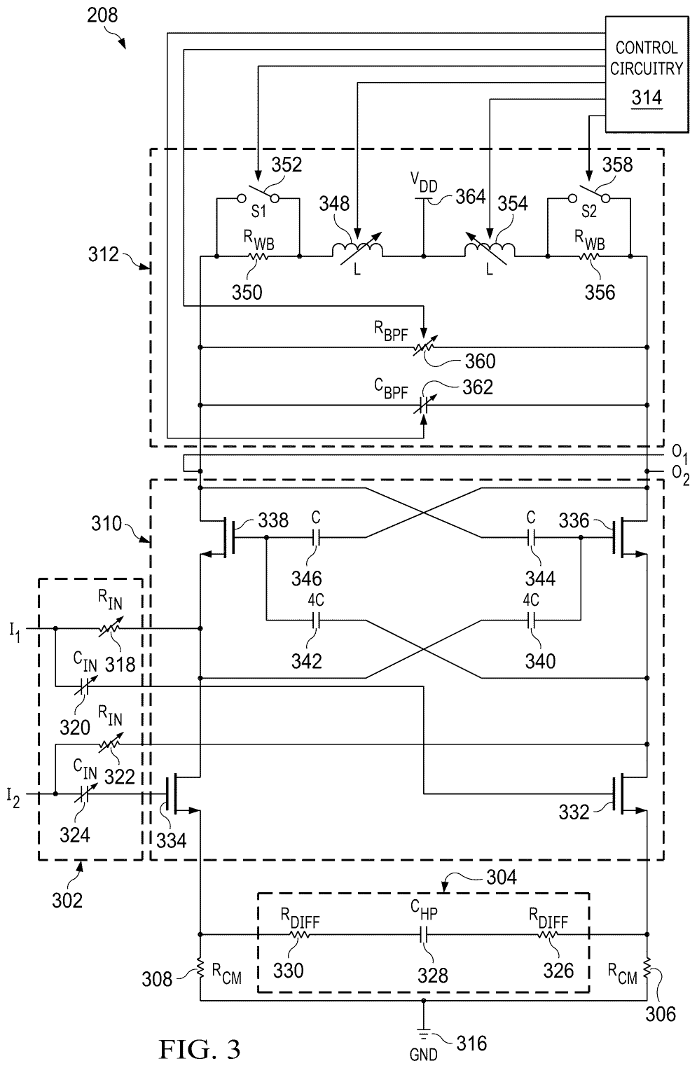

In the illustrated example of FIG. 1, each of the DSAs 128₁-128_{M} is implemented by at least one of analog circuitry or digital circuitry. An example electronic circuit that can implement any of the DSAs 128₁-128_{M} is illustrated and described in connection with FIG. 3. In the example of FIG. 1, the DSAs 128₁-128_{M} are coupled to the matching networks 126₁-126_{M}. For example, the first input and the second input of respective DSAs are coupled to the first output and the second output of respective matching networks, respectively. In the example of FIG. 1, the DSAs 128₁-128_{M} are coupled to the sampling circuits 130₁-130_{M}. For example, the first output and the second output of respective DSAs are coupled to the first input and the second input of respective sampling circuits, respectively.

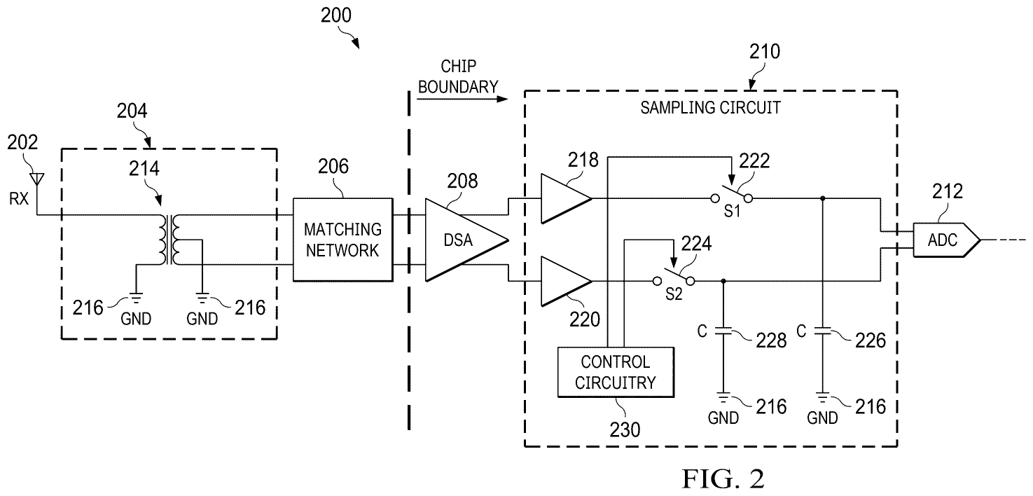

In the illustrated example of FIG. 1, each of the sampling circuits 130₁-130_{M} is implemented by at least one of analog circuitry or digital circuitry. An example implementation of a sampling circuit that can implement any of the sampling circuits 130₁-130_{M} is illustrated and described in connection with FIG. 2. In the example of FIG. 1, the sampling circuits 130₁-130_{M} are coupled to the DSAs 128₁-128_{M}. For example, the first input and the second input of respective sampling circuits are coupled to the first output and the second output of respective DSAs, respectively. Also, in the example of FIG. 1, the sampling circuits 130₁-130_{M} are coupled to the ADCs 132₁-132_{M}. For example, the first output and the second output of respective sampling circuits are coupled to the first input and the second input of respective ADCs, respectively.

In the illustrated example of FIG. 1, each of the ADCs 132₁-132_{M} is implemented by at least one of analog circuitry or digital circuitry. In the example of FIG. 1, the ADCs 132₁-132_{M} are coupled to the sampling circuits 130₁-130_{M}. For example, the first input and the second input of respective ADCs are coupled to the first output and the second output of respective sampling circuits, respectively. Also, in the example of FIG. 1, the ADCs 132₁-132_{M} are coupled to the processor circuit 114. For example, the output of respective ADCs is coupled to the input of the processor circuit 114.

In the illustrated example of FIG. 1, the processor circuit 114 may be implemented by analog circuitry and/or digital circuitry. For example, in some embodiment, processor circuit 114 may be implemented as a generic or custom processor or controller coupled to a memory and configured to execute instructions from such memory. In some embodiments, the processor circuit 114 may be implemented by a generic or custom DSP, a generic or custom microcontroller, an FFT engine, a combined DSP and microcontroller processor, an FPGA, or an application specific integrated circuit (ASIC). In the example of FIG. 1, the input of the processor circuit 114 is coupled to outputs of respective ones of the ADCs 132₁-132_{M}. Also, in the example of FIG. 1, the processor circuit 114 is coupled to the feedback switches 134₁-134_{N}. For example, the output of the processor circuit 114 is coupled to the control terminals of respective feedback switches. While in the example of FIG. 1 the output of the processor circuit 114 is illustrated as a single terminal, in some embodiments, the output may be implemented by one or more outputs corresponding to the number of the feedback switches 134₁-134_{N}. In some examples, the processor circuit 114 is coupled to the digital signal generation circuit 102.

In the illustrated example of FIG. 1, each of the receive antennas 110₁-110_{M} receives a signal from an environment in a field of view of the RF circuit 100. For example, each of the receive antennas 110₁-110_{M} receives cell signal from the environment. In additional or alternative examples, each of the receive antennas 110₁-110_{M} receives a radar frame from the environment. In the example of FIG. 1, each of the balun circuits 124₁-124_{M} converts a single ended received signal into a differential received signal and forwards the differential received signal to the matching networks 126₁-126_{M}. In the example of FIG. 1, the matching networks 126₁-126_{M} match the input impedance of the receivers 112₁-112_{M} to the impedance of the receive antennas 110₁-110_{M}.

In the illustrated example of FIG. 1, the matching networks 126₁-126_{M} provide the differential received signals to the DSAs 128₁-128_{M}. In the example of FIG. 1, each of the DSAs 128₁-128_{M} adjusts the gain of the differential received signal to be within a threshold range for the ADCs 132₁-132_{M}. In the example of FIG. 1, each of the sampling circuits 130₁-130_{M} samples the differential received signal and provides the sample(s) to the ADCs 132₁-132_{M}. Also, in the example of FIG. 1, each of the ADCs 132₁-132_{M} converts the differential received signal from the analog domain to the digital domain.

In some examples, the RF circuit 100 includes digital front end (DFE) circuitry between the ADCs 132₁-132_{M} and the processor circuit 114. For example, the DFE circuitry receives digital signals from the receivers 112₁-112_{M} and performs decimation filtering or other processing operations on the digital signals, for example, to adjust the data transfer rate of the digital signals. Also or alternatively, the DFE circuitry may perform other operations on the digital signals such as direct current (DC) offset removal or compensation (for example, digital compensation) of non-idealities in the receivers 112₁-112_{M} such as inter-receiver gain imbalance non-ideality, inter-receiver phase imbalance non-ideality, and the like.

In the illustrated example of FIG. 1, the processor circuit 114 is to perform at least a portion of signal processing on the digital signals resulting from a received analog signal. In some examples, the processor circuit 114 is to transmit the results of signal processing. For example, the processor circuit 114 transmits the results of signal processing to a processing unit. In some examples, the processor circuit 114 interfaces with another device via a high-speed interface or a serial peripheral interface (SPI). In the example of FIG. 1, the processor circuit 114 performs an FFT on each received signal. In some examples, the processor circuit 114 receives control information (for example, timing of signals, power level, triggering of monitoring functions, etc.) via an SPI. For example, responsive to the control information, the processor circuit 114 provides data parameters or provides control signals to the digital signal generation circuit 102.

In some examples, the processor circuit 114 triggers sampling of one or more of the analog signals communicated by the PAs 122₁-122_{N} to the transmit antennas 108₁-108_{N}. For example, to trigger sampling of an analog signal by sending a control signal to one of the feedback switches 134₁-134_{N}. In the example of FIG. 1, the control terminal of each of the feedback switches 134₁-134_{N} is coupled to the output of the processor circuit 114. Also, the first current path terminal of each of the feedback switches 134₁-134_{N} is coupled to the output of the PAs 122₁-122_{N}, respectively, and the second current path terminal of each of the feedback switches 134₁-134_{N} is coupled to the input of the balun circuit 124_{FB}. In the example of FIG. 1, each of the feedback switches 134₁-134_{N} is implemented by a transistor such as a field-effect transistor (FET).

In the illustrated example of FIG. 1, the feedback receiver 112_{FB} is implemented and coupled similarly as described with respect to the receivers 112₁-112_{M} unless described otherwise. As described above, in the example of FIG. 1, the input of the balun circuit 124_{FB} is coupled to the second current path terminal of each of the feedback switches 134₁-134_{N}. Also, the output of the ADC 132_{FB} is coupled to the input of the feedback circuit 136. In the example of FIG. 1, the feedback circuit 136 is implemented by at least one of analog circuitry or digital circuitry. Also, in the example of FIG. 1, the input of the feedback circuit 136 is coupled to the output of the ADC 132_{FB} and the output of the feedback circuit 136 is coupled to the second input of respective ones of the DACs 116₁-116_{N}. While in the example of FIG. 1 the output of the feedback circuit 136 is illustrated as a single terminal, in some embodiments, the output may be implemented by one or more outputs corresponding to the number of the DACs 116₁-116_{N}.

In the illustrated example of FIG. 1, the feedback circuit 136 samples, via the feedback receiver 112_{FB}, an analog signal communicated by one of the PAs 122₁-122_{N} to one of the transmit antennas 108₁-108_{N}. For example, the feedback circuit 136 determines a non-linearity in one of the PAs 122₁-122_{N} and determines one or more digital pre-distortion (DPD) coefficients to correct for the non-linearity. Based on the one or more DPD coefficients, the feedback circuit 136 adjusts one of the DACs 116₁-116_{N} corresponding to the one of the PAs 122₁-122_{N} sampled by the feedback receiver 112_{FB}. In this manner, the feedback circuit 136 can improve the adjacent channel power ratio (ACPR) between the transmitters 104₁-104_{N} of the RF circuit 100.

FIG. 2 is a block diagram of receiver 200, according to an embodiment of the present disclosure. Any of receivers 112₁-112_{M} of FIG. 1 may be implemented as receiver 200. In the example of FIG. 2, the receiver 200 includes receive antenna 202, balun circuit 204, matching network 206, DSA 208, sampling circuit 210, and ADC 212. In some embodiments, the receive antenna 202, the balun circuit 204, and the matching network 206 are external to a chip (for example, an SoC, an IC, etc.), and the DSA 208, the sampling circuit 210, and the ADC 212 are internal to the chip (for example, the SoC, the IC, etc.). Other implementations are also possible.

In the example of FIG. 2, the balun circuit 204 has an input, a first output, and a second output and the ADC has a first input, a second input, and an output. In the example of FIG. 2, each of the matching network 206, the DSA 208, and the sampling circuit 210 has a first input, a second input, a first output, and a second output.

In the illustrated example of FIG. 2, the balun circuit 204 includes transformer 214 and ground terminal 216. For example, the ground terminal 216 is at a voltage of zero volts (V). In the example of FIG. 2, the transformer 214 includes a first input, a second input, a first output, a second output, and a center tap. In the example of FIG. 2, the input of the balun circuit 204 is coupled to the receive antenna 202. For example, the first input of the transformer 214 is coupled to the receive antenna 202 and, as such, is coupled to the input of the balun circuit 204. Also, for example, the second input of the transformer 214 is coupled to the ground terminal 216.

In the illustrated example of FIG. 2, the first output and the second output of the balun circuit 204 are coupled to the first input and the second input of the matching network 206, respectively. For example, the first output of the transformer 214 is coupled to the first input of the matching network 206 and, as such, is coupled to the first output of the balun circuit 204. Also, for example, the second output of the transformer 214 is coupled to the second input of the matching network 206 and, as such, the second output of the transformer 214 is coupled to the second output of the balun circuit 204. In the example of FIG. 2, the center tap of the transformer 214 is coupled to the ground terminal 216.

In the illustrated example of FIG. 2, the matching network 206 may be implemented by an analog circuitry and/or digital circuitry. In the example of FIG. 2, the first input and the second input of the matching network 206 are coupled to the first output and the second output of the balun circuit 204, respectively. For example, the first input and the second input of the matching network 206 are coupled to the first output and the second output of the transformer 214, respectively. In the example of FIG. 2, the first output and the second output of the matching network 206 are coupled to the first input and the second input of the DSA 208.

In the illustrated example of FIG. 2, the DSA 208 may be implemented by an analog circuitry and/or digital circuitry. FIG. 3 shows a possible implementation of DSA 208, according to an embodiment of the present disclosure.

In the example of FIG. 2, the first input and the second input of the DSA 208 are coupled to the first output and the second output of the matching network 206, respectively. Also, in the example of FIG. 2, the first output and the second output of the DSA 208 are coupled to the first input and the second input of the sampling circuit 210, respectively.

In the illustrated example of FIG. 2, the sampling circuit 210 includes first buffer 218, second buffer 220, first sampling switch 222, second sampling switch 224, first sampling capacitor 226, second sampling capacitor 228, and control circuitry 230. In the example of FIG. 2, each of the buffer 218 and the buffer 220 has an input and an output. Also, in the example of FIG. 2, each of the buffer 218 and the buffer 220 is implemented by analog circuitry and/or digital circuitry.

In the illustrated example of FIG. 2, each of the sampling switch 222 and the sampling switch 224 has a control terminal, a first current path terminal, and a second current path terminal. For example, each of the sampling switch 222 and the sampling switch 224 is implemented by a transistor such as a field-effect transistor (FET). In the example of FIG. 2, each of the sampling capacitor 226 and the sampling capacitor 228 has a first terminal and a second terminal. Also, each of the sampling capacitor 226 and the sampling capacitor 228 has a capacitance of C. In the example of FIG. 2, the control circuitry 230 has a first output and a second output. For example, the control circuitry 230 is implemented by at least one of analog circuitry or digital circuitry.

In the illustrated example of FIG. 2, the first input of the sampling circuit 210 is coupled to the first output of the DSA 208. For example, the input of the buffer 218 is coupled to the first output of the DSA 208 and, as such, is coupled to the first input of the sampling circuit 210. Also, the output of the buffer 218 is coupled to the second current path terminal of the sampling switch 222. In the example of FIG. 2, the second input of the sampling circuit 210 is coupled to the second output of the DSA 208. For example, the input of the buffer 220 is coupled to the second output of the DSA 208 and, as such, is coupled to the second input of the sampling circuit 210. Also, the output of the buffer 220 is coupled to the second current path terminal of the sampling switch 224.

In the illustrated example of FIG. 2, the first current path terminal of the sampling switch 222 is coupled to the first terminal of the sampling capacitor 226 and the second current path terminal of the sampling switch 222 is coupled to the output of the buffer 218. Also, the control terminal of the sampling switch 222 is coupled to the first output of the control circuitry 230. In the example of FIG. 2, the first current path terminal of the sampling switch 224 is coupled to the first terminal of the sampling capacitor 228 and the second current path terminal of the sampling switch 224 is coupled to the output of the buffer 220. Also, the control terminal of the sampling switch 224 is coupled to the second output of the control circuitry 230.

In the illustrated example of FIG. 2, the first output of the sampling circuit 210 is coupled to the first input of the ADC 212. For example, the first terminal of the sampling capacitor 226 is coupled first current path terminal of the sampling switch 222 and the first input of the ADC 212. As such, the first terminal of the sampling capacitor 226 is coupled to the first output of the sampling circuit 210. Also, the second terminal of the sampling capacitor 226 is coupled to the ground terminal 216. In the example of FIG. 2, the second output of the sampling circuit 210 is coupled to the second input of the ADC 212. For example, the first terminal of the sampling capacitor 228 is coupled first current path terminal of the sampling switch 224 and the second input of the ADC 212. As such, the first terminal of the sampling capacitor 228 is coupled to the second output of the sampling circuit 210. Also, the second terminal of the sampling capacitor 228 is coupled to the ground terminal 216.

In the illustrated example of FIG. 2, the buffer 218 and the buffer 220 buffer a differential analog signal provided by the DSA 208. Based on control signals from the control circuitry 230, the sampling switch 222 and the sample switch 224 are enabled (conduct current) to charge the sampling capacitor 226 and the sampling capacitor 228, respectively. As such, the sampling circuit 210 samples the differential analog signal provided by the DSA 208.

In the illustrated example of FIG. 2, the ADC 212 is implemented by at least one of analog circuitry or digital circuitry. In the example of FIG. 2, the first input and the second input of the ADC 212 are coupled to the first output and the second output of the sampling circuit 210, respectively. For example, the first input of the ADC 212 is coupled to the first terminal of the sampling capacitor 226 and the second input of the ADC 212 is coupled to the first terminal of the sampling capacitor 228. In the example of FIG. 2, the output of the ADC 212 is coupled to the input of a processor circuit. For example, the output of the ADC 212 is coupled to the input of the processor circuit 114.

FIG. 3 is a schematic diagram of an example implementation of the DSA 208 of FIG. 2. In the example of FIG. 3, the DSA 208 includes configurable input network 302, high pass filter 304, first common mode resistor 306, second common mode resistor 308, low noise amplifier (LNA) 310, configurable output network 312, and control circuitry 314. In the example of FIG. 3, the configurable input network 302 has a first input, a second input, a first output, a second output, a third output, and a fourth output. In the example of FIG. 3, each of the high pass filter 304, the common mode resistor 306, the common mode resistor 308 has a first terminal and a second terminal.

In the illustrated example of FIG. 3, the LNA 310 has a first input, a second input, a third input, a fourth input, a first output, a second output, a first terminal, and a second terminal. In the example of FIG. 3, the configurable output network 312 has a first terminal, a second terminal, a first control terminal, a second control terminal, a third control terminal, a fourth control terminal, a fifth control terminal, and a sixth control terminal. While in the example of FIG. 3 the first control terminal, the second control terminal, the third control terminal, the fourth control terminal, the fifth control terminal, and the sixth control terminal of the configurable output network 312 are illustrated as a single terminal, in some embodiments, one or more of the first control terminal, the second control terminal, the third control terminal, the fourth control terminal, the fifth control terminal, or the sixth control terminal may be implemented by one or more terminals. In the example of FIG. 3, the control circuitry 314 has a first output, a second output, a third output, a fourth output, a fifth output, and a sixth output. While in the example of FIG. 3 the first output, the second output, the third output, the fourth output, the fifth output, and the sixth output of the control circuitry 314 are illustrated as a single output, in some embodiments, one or more of the first output, the second output, the third output, the fourth output, the fifth output, or the sixth output may be implemented by one or more outputs.

In the illustrated example of FIG. 3, the first input of the configurable input network 302 is coupled to the first input of the DSA 208 and the second input of the configurable input network 302 is coupled to the second input of the DSA 208. In the example of FIG. 3, the first output of the configurable input network 302 is coupled to the fourth input of the LNA 310 and the second output of the configurable input network 302 is coupled to the third input of the LNA 310. Also, in the example of FIG. 3, the third output of the configurable input network 302 is coupled to the first input of the LNA 310 and the fourth output of the configurable input network 302 is coupled to the second input of the LNA 310.

In the illustrated example of FIG. 3, the first terminal of the high pass filter 304 is coupled to the first terminal of the LNA 310 and the first terminal of the common mode resistor 308. Also, the second terminal of the high pass filter 304 is coupled to the second terminal of the LNA 310 and the first terminal of the common mode resistor 306. As such, the high pass filter 304 is coupled between the first and second terminals of the LNA 310. In the example of FIG. 3, the common mode resistor 306 has a resistance of R_{CM}. Also, the first terminal of the common mode resistor 306 is coupled to the second terminal of the LNA 310 and the second terminal of the high pass filter 304. In the example of FIG. 3, the second terminal of the common mode resistor 306 is coupled to an example ground terminal 316 (also referred to as ground). For example, in some embodiments, the ground terminal 316 is at a voltage of zero V. In some examples, the ground terminal 316 is implemented by the ground terminal 216. In the illustrated example of FIG. 3, the common mode resistor 308 has a resistance of R_{CM}. In the example of FIG. 3, the first terminal of the common mode resistor 308 is coupled to the first terminal of the LNA 310 and the first terminal of the high pass filter 304. Also, the second terminal of the common mode resistor 308 is coupled to the ground terminal 316 (coupled to ground).

In the illustrated example of FIG. 3, the first input of the LNA 310 is coupled to the third output of the configurable input network 302. Also, in the example of FIG. 3, the second input of the LNA 310 is coupled to the fourth output of the configurable input network 302. In the example of FIG. 3, the third input of the LNA 310 is coupled to the second output of the configurable input network 302. Also, in the example of FIG. 3, the fourth input of the LNA 310 is coupled to the first output of the configurable input network 302.

In the illustrated example of FIG. 3, the first output of the LNA 310 is coupled to the first terminal of the configurable output network 312. In the example of FIG. 3, the first output of the LNA 310 is coupled to the first output of the DSA 208. Also, in the example of FIG. 3, the second output of the LNA 310 is coupled to the second terminal of the configurable output network 312. In the example of FIG. 3, the second output of the LNA 310 is coupled to the second output of the DSA 208. Also, in the example of FIG. 3, the first terminal of the LNA 310 is coupled to the first terminal of the high pass filter 304 and the first terminal of the common mode resistor 308. In the example of FIG. 3, the second terminal of the LNA 310 is coupled to the second terminal of the high pass filter 304 and the first terminal of the common mode resistor 306.

In the illustrated example of FIG. 3, the first terminal of the configurable output network 312 is coupled to the first output of the LNA 310. In the example of FIG. 3, the second terminal of the configurable output network 312 is coupled to the second output of the LNA 310. Also, in the example of FIG. 3, the first control terminal of the configurable output network 312 is coupled to the first output of the control circuitry 314. In the example of FIG. 3, the second control terminal of the configurable output network 312 is coupled to the second output of the control circuitry 314.

In the illustrated example of FIG. 3, the third control terminal of the configurable output network 312 is coupled to the third output of the control circuitry 314. In the example of FIG. 3, the fourth control terminal of the configurable output network 312 is coupled to the fourth output of the control circuitry 314. Also, in the example of FIG. 3, the fifth control terminal of the configurable output network 312 is coupled to the fifth output of the control circuitry 314. In the example of FIG. 3, the sixth control terminal of the configurable output network 312 is coupled to the sixth output of the control circuitry 314.

In the illustrated example of FIG. 3, the configurable input network 302 includes a first example input resistor 318, a first example input capacitor 320, a second example input resistor 322, a second example input capacitor 324. In the example of FIG. 3, each of the input resistor 318, the input capacitor 320, the input resistor 322, and the input capacitor 324 has a first terminal and a second terminal. Also, in the example of FIG. 3, the input resistor 318 has a resistance of up to R_{IN} Ohms (Ω). For example, the input resistor 318 is a variable resistor with a tunable resistance (configurable resistance) between zero Ω and R_{IN}Ω. In the example of FIG. 3, the first terminal of the input resistor 318 is coupled to the second terminal of the input capacitor 320. Also, the second terminal of the input resistor 318 is coupled to the first output of the configurable input network 302. For example, the second terminal of the input resistor 318 is coupled to the fourth input of the LNA 310.

In the illustrated example of FIG. 3, the input capacitor 320 has a capacitance of up to C_{IN} farads (F). For example, the input capacitor 320 is a variable capacitor with a tunable capacitance (configurable capacitance) between zero F and C_{IN} F. In the example of FIG. 3, the first terminal of the input capacitor 320 is to operate as the fourth output of the configurable input network 302. For example, the first terminal of the input capacitor 320 is coupled to second input of the LNA 310. Also, the second terminal of the input capacitor 320 is coupled to the first terminal of the input resistor 318. As such, the first terminal of the input resistor 318 and the second terminal of the input capacitor 320 are coupled to the first input of the configurable input network 302.

In the illustrated example of FIG. 3, the input resistor 322 has a resistance of up to R_{IN}Ω. For example, the input resistor 322 is a variable resistor with a tunable resistance between zero Ω and R_{IN}Ω. In the example of FIG. 3, the first terminal of the input resistor 322 is coupled to the second terminal of the input capacitor 324. Also, the second terminal of the input resistor 322 is coupled to the second output of the configurable input network 302. For example, the second terminal of the input resistor 322 is coupled to the third input of the LNA 310.

In the illustrated example of FIG. 3, the input capacitor 324 has a capacitance of up to C_{IN} F. For example, the input capacitor 324 is a variable capacitor with a tunable capacitance between zero F and C_{IN} F. In the example of FIG. 3, the first terminal of the input capacitor 324 is coupled to the third output of the configurable input network 302. For example, the first terminal of the input capacitor 324 is coupled to the first input of the LNA 310. Also, the second terminal of the input capacitor 324 is coupled to the first terminal of the input resistor 322. As such, the first terminal of the input resistor 322 and the second terminal of the input capacitor 324 are coupled to the second input of the configurable input network 302.

In the illustrated example of FIG. 3, each of the input resistor 318, the input capacitor 320, the input resistor 322, and the input capacitor 324 is illustrated as a two-terminal component. In some embodiments, each of the input resistor 318, the input capacitor 320, the input resistor 322, and the input capacitor 324 includes at least one control terminal to allow for tuning of the impedance of the components. For example, as a variable component, the input resistor 318 is implemented by two or more resistors in parallel where at least one of the two or more resistors is coupled in series with a switch to allow for a control signal to tune the resistance of the input resistor 318. As such, each of the input resistor 318, the input capacitor 320, the input resistor 322, and the input capacitor 324 includes at least one control terminal coupled to a controller such as the control circuitry 314.

In the illustrated example of FIG. 3, the high pass filter 304 includes first resistor 326, high pass capacitor 328, and second resistor 330. Each of the resistor 326, the high pass capacitor 328, and the resistor 330 of the example of FIG. 3 has a first terminal and a second terminal. In the example of FIG. 3, the resistor 326 has a resistance of R_{DIFF}. Also, the first terminal of the resistor 326 is coupled to the second terminal of the high pass capacitor 328. In the example of FIG. 3, the second terminal of the resistor 326 is coupled to the second terminal of the LNA 310 and the first terminal of the common mode resistor 306. As such, the second terminal of the resistor 326 is coupled to the second terminal of the high pass filter 304.

In the illustrated example of FIG. 3, the high pass capacitor 328 has a capacitance of C_{HP}. In the example of FIG. 3, the first terminal of the high pass capacitor 328 is coupled to the second terminal of the resistor 330. Also, the second terminal of high pass capacitor 328 is coupled the first terminal of the resistor 326. In the example of FIG. 3, the resistor 330 has a resistance of R_{DIFF}. Also, the first terminal of the resistor 330 is coupled to the first terminal of the LNA 310 and the first terminal of the common mode resistor 308. As such, the first terminal of the resistor 330 is coupled to the first terminal of the high pass filter 304. In the example of FIG. 3, the second terminal of the resistor 330 is coupled to the first terminal of the high pass capacitor 328. As described above, the high pass capacitor 328 is coupled between the first and second terminals of the LNA 310, the resistor 330 is coupled between the first terminal of the LNA 310 and the high pass capacitor 328, and the resistor 326 is coupled between the second terminal of the LNA 310 and the high pass capacitor 328.

In the illustrated example of FIG. 3, the LNA 310 includes first transconductance transistor 332, second transconductance transistor 334, third transconductance transistor 336, fourth transconductance transistor 338, first cross-coupling capacitor 340, second cross-coupling capacitor 342, third cross-coupling capacitor 344, fourth cross-coupling capacitor 346. In the example of FIG. 3, the cross-coupling capacitor 340, the cross-coupling capacitor 342, the cross-coupling capacitor 344, and the cross-coupling capacitor 346 has a first terminal and a second terminal. Also, in the example of FIG. 3, each of the transconductance transistor 332, the transconductance transistor 334, the transconductance transistor 336, and the transconductance transistor 338 has a control terminal (gate terminal), a first current path terminal (drain terminal), and a second current path terminal (source terminal).

In the illustrated example of FIG. 3, each of the transconductance transistor 332, the transconductance transistor 334, the transconductance transistor 336, and the transconductance transistor 338 is implemented by a transistor such as a negative channel (N-channel) FET. For example, each of the transconductance transistor 332, the transconductance transistor 334, the transconductance transistor 336, and the transconductance transistor 338 is implemented by an N-channel metal-oxide semiconductor (MOS) FET. In the example of FIG. 3, the control terminal of the transconductance transistor 332 is coupled to the fourth output of the configurable input network 302. For example, the control terminal of the transconductance transistor 332 is coupled to the first terminal of the input capacitor 320. As such, the control terminal of the transconductance transistor 332 is coupled to the fourth input of the LNA 310.

In the illustrated example of FIG. 3, the first current path terminal of the transconductance transistor 332 is coupled to the second output of the configurable input network 302. For example, the first current path terminal of the transconductance transistor 332 is coupled to the second terminal of the input resistor 322. As such, the first current path terminal of the transconductance transistor 332 is coupled to the third input of the LNA 310. In the example of FIG. 3, the first current path terminal of the transconductance transistor 332 is also coupled to the second current path terminal of the transconductance transistor 336 and the second terminal of the cross-coupling capacitor 342. In the example of FIG. 3, the second current path terminal of the transconductance transistor 332 is coupled to the second terminal of the high pass filter 304 and the first terminal of the common mode resistor 306. As such, the second current path terminal of the transconductance transistor 332 is coupled to the second terminal of the LNA 310.

In the illustrated example of FIG. 3, the control terminal of the transconductance transistor 334 is coupled to the third output of the configurable input network 302. For example, the control terminal of the transconductance transistor 334 is coupled to the first terminal of the input capacitor 324. As such, the control terminal of the transconductance transistor 334 is coupled to the first input of the LNA 310. In the example of FIG. 3, the first current path terminal of the transconductance transistor 334 is coupled to the first output of the configurable input network 302. For example, the first current path terminal of the transconductance transistor 334 is coupled to the second terminal of the input resistor 318. As such, the first current path terminal of the transconductance transistor 334 is coupled to the fourth input of the LNA 310.

In the illustrated example of FIG. 3, the first current path terminal of the transconductance transistor 334 is also coupled to the second current path terminal of the transconductance transistor 338 and the second terminal of the cross-coupling capacitor 340. In the example of FIG. 3, the second current path terminal of the transconductance transistor 334 is coupled to the first terminal of the high pass filter 304 and the first terminal of the common mode resistor 308. As such, the second current path terminal of the transconductance transistor 334 is coupled to the first terminal of the LNA 310.

In the illustrated example of FIG. 3, the control terminal of the transconductance transistor 336 is coupled to the first terminal of the cross-coupling capacitor 340 and the first terminal of the cross-coupling capacitor 344. In the example of FIG. 3, the first current path terminal of the transconductance transistor 336 is coupled to the second terminal of the configurable output network 312 and the second terminal of the cross-coupling capacitor 346. As such, the first current path terminal of the transconductance transistor 336 is coupled to the second output of the LNA 310. Also, the second current path terminal of the transconductance transistor 336 is coupled to the first current path terminal of the transconductance transistor 332 and the second terminal of the cross-coupling capacitor 342.

In the illustrated example of FIG. 3, the control terminal of the transconductance transistor 338 is coupled to the first terminal of the cross-coupling capacitor 342 and the first terminal of the cross-coupling capacitor 346. In the example of FIG. 3, the first current path terminal of the transconductance transistor 338 is coupled to the first terminal of the configurable output network 312 and the second terminal of the cross-coupling capacitor 344. As such, the first current path terminal of the transconductance transistor 338 is coupled to the first output of the LNA 310. Also, the second current path terminal of the transconductance transistor 338 is coupled to the first current path terminal of the transconductance transistor 334 and the second terminal of the cross-coupling capacitor 340.

In the illustrated example of FIG. 3, the cross-coupling capacitor 340 has a capacitance of 4 C. In the example of FIG. 3, the first terminal of the cross-coupling capacitor 340 is coupled to the control terminal of the transconductance transistor 336 and the first terminal of the cross-coupling capacitor 344. Also, the second terminal of the cross-coupling capacitor 340 is coupled to the first current path terminal of the transconductance transistor 334 and the second current path terminal of the transconductance transistor 338. As such, the cross-coupling capacitor 340 cross-couples the control terminal of the transconductance transistor 336 and the second current path terminal of the transconductance transistor 338.

In the illustrated example of FIG. 3, the cross-coupling capacitor 342 has a capacitance of 4 C. In the example of FIG. 3, the first terminal of the cross-coupling capacitor 342 is coupled to the control terminal of the transconductance transistor 338 and the first terminal of the cross-coupling capacitor 346. Also, the second terminal of the cross-coupling capacitor 342 is coupled to the first current path terminal of the transconductance transistor 332 and the second current path terminal of the transconductance transistor 336. As such, the cross-coupling capacitor 342 cross-couples the control terminal of the transconductance transistor 338 and the second current path terminal of the transconductance transistor 336.

In the illustrated example of FIG. 3, the cross-coupling capacitor 344 has a capacitance of C (one fourth of the capacitance of the cross-coupling capacitor 340). In the example of FIG. 3, the first terminal of the cross-coupling capacitor 344 is coupled to the control terminal of the transconductance transistor 336 and the first terminal of the cross-coupling capacitor 340. Also, the second terminal of the cross-coupling capacitor 344 is coupled to the first terminal of the configurable output network 312 and the first current path terminal of the transconductance transistor 338. As such, the cross-coupling capacitor 344 cross-couples the control terminal of the transconductance transistor 336 and the first current path terminal of the transconductance transistor 338.

In the illustrated example of FIG. 3, the cross-coupling capacitor 346 has a capacitance of C (one fourth of the capacitance of the cross-coupling capacitor 342). In the example of FIG. 3, the first terminal of the cross-coupling capacitor 346 is coupled to the control terminal of the transconductance transistor 338 and the first terminal of the cross-coupling capacitor 342. Also, the second terminal of the cross-coupling capacitor 346 is coupled to the second terminal of the configurable output network 312 and the first current path terminal of the transconductance transistor 336. As such, the cross-coupling capacitor 346 cross-couples the control terminal of the transconductance transistor 338 and the first current path terminal of the transconductance transistor 336.

As described above, the first current path terminal of the transconductance transistor 334 is also coupled to the first output of the LNA 310. For example, the first current path terminal of the transconductance transistor 334 is coupled to the first output of the LNA 310 via the cross-coupling capacitor 340 and the cross-coupling capacitor 344. Also, the first current path terminal of the transconductance transistor 332 is coupled to the second output of the LNA 310. For example, the first current path terminal of the transconductance transistor 332 is coupled to the second output of the LNA 310 via the cross-coupling capacitor 342 and the cross-coupling capacitor 346.

In the illustrated example of FIG. 3, the configurable output network 312 includes first inductor 348, first resistor 350, first switch 352, second inductor 354, second resistor 356, second switch 358, an example resistor 360, and an example capacitor 362. In the example of FIG. 3, each of the switch 352 and the switch 358 has a control terminal, a first current path terminal, and a second current path terminal. Also, each of the inductor 348, the resistor 350, the inductor 354, the resistor 356, the resistor 360, and the capacitor 362 has a first terminal and a second terminal. In the example of FIG. 3, each of the inductor 348, the inductor 354, the resistor 360, and the capacitor 362 has a control terminal. While in the example of FIG. 3 the control terminal of each of the inductor 348, the inductor 354, the resistor 360, and the capacitor 362 is illustrated as a single terminal, in some embodiments, one or more of the control terminals of the inductor 348, the inductor 354, the resistor 360, and the capacitor 362 may be implemented by one or more terminals.

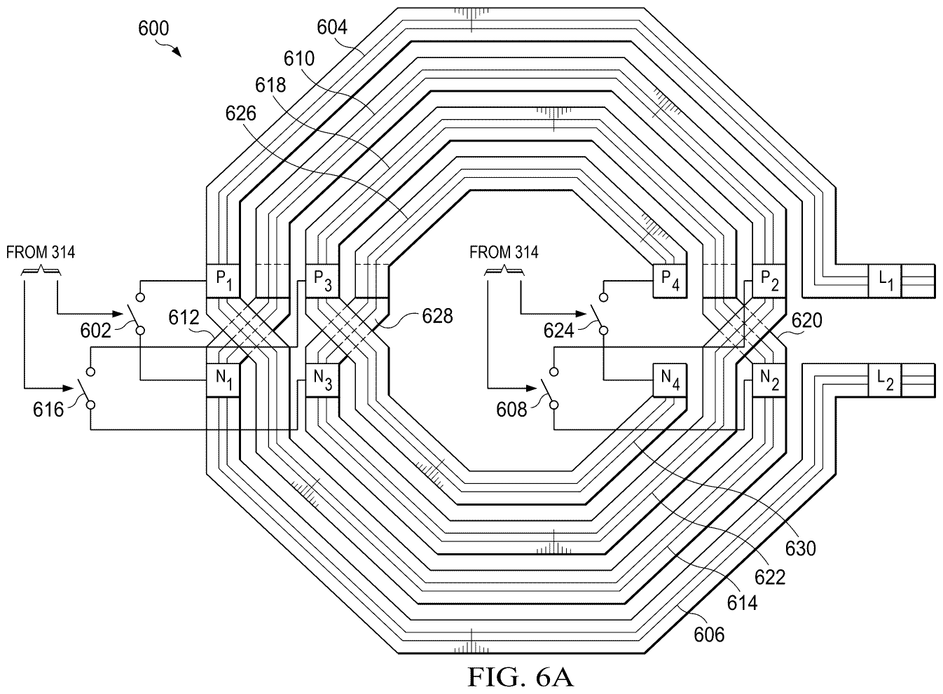

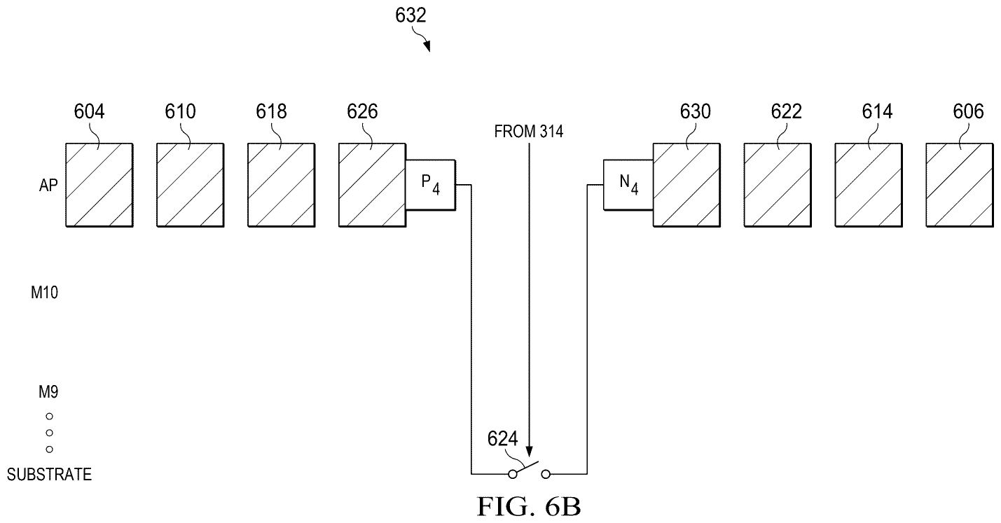

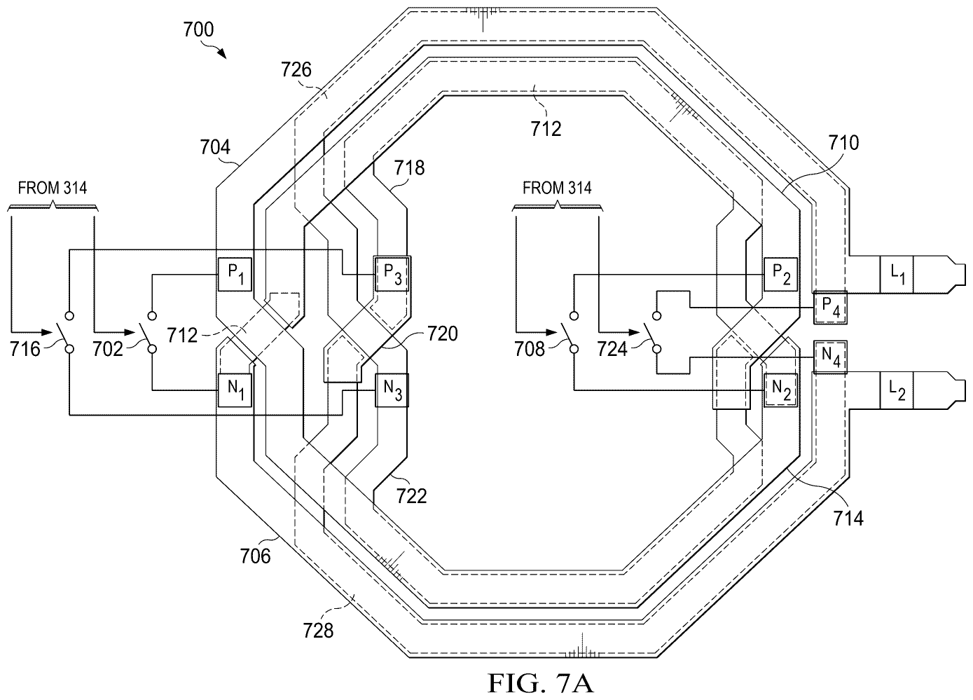

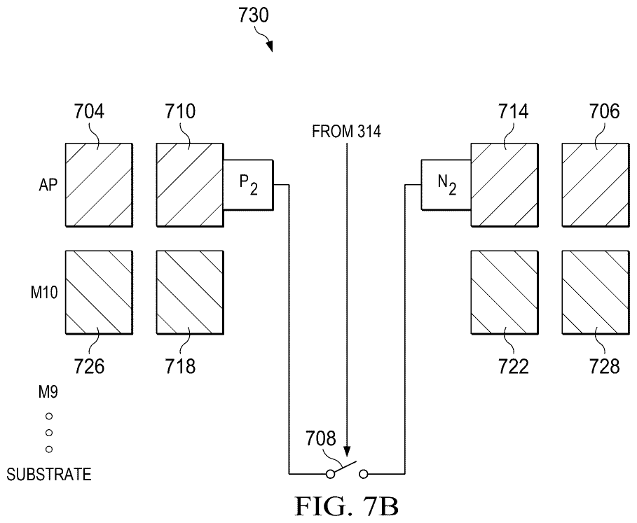

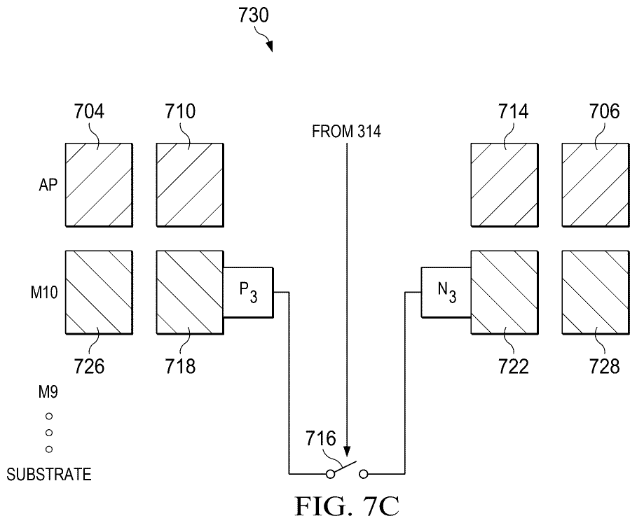

In the illustrated example of FIG. 3, the inductor 348 has an inductance of up to L Henries (H). For example, the inductor 348 is a variable inductor with a tunable inductance between zero H and L H. Example implementations of inductors that can implement the inductor 348 are illustrated and described in connection with FIGS. 6A-6B and 7A-7C, according to some embodiments of the present disclosure. In the example of FIG. 3, the control terminal of the inductor 348 is coupled to the fourth output of the control circuitry 314. As such, the control terminal of the inductor 348 is coupled to the fourth control terminal of the configurable output network 312. In the example of FIG. 3, the first terminal of the inductor 348 is coupled to the second terminal of the resistor 350 and the second current path terminal of the switch 352. Also, the second terminal of the inductor 348 is coupled to the second terminal of the inductor 354 and an example supply terminal 364. For example, the supply terminal 364 is at a voltage of V_{DD} V.

In the illustrated example of FIG. 3, the resistor 350 has a resistance of R_{WB}Ω. In the example of FIG. 3, the first terminal of the resistor 350 is coupled to the first current path terminal of the switch 352, the first terminal of the resistor 360, the first terminal of the capacitor 362, the first current path terminal of the transconductance transistor 338, and the second terminal of the cross-coupling capacitor 344. Also, the second terminal of the resistor 350 is coupled to the first terminal of the inductor 348 and the second current path terminal of the switch 352.

In the illustrated example of FIG. 3, the switch 352 is implemented by a transistor such as an FET. In the example of FIG. 3, the control terminal of the switch 352 is coupled to the third output of the control circuitry 314. As such, the control terminal of the switch 352 is coupled to the third control terminal of the configurable output network 312. In the example of FIG. 3, the first current path terminal of the switch 352 is coupled to the first terminal of the resistor 350, the first terminal of the resistor 360, the first terminal of the capacitor 362, the first current path terminal of the transconductance transistor 338, and the second terminal of the cross-coupling capacitor 344. Also, the second current path terminal of the switch 352 is coupled to the first terminal of the inductor 348 and the second terminal of the resistor 350.

In the illustrated example of FIG. 3, the inductor 354 has an inductance of up to L H. For example, the inductor 354 is a variable inductor with a tunable inductance between zero H and L H. Example implementations of inductors that can implement the inductor 354 are illustrated and described in connection with FIGS. 6A-6B and 7A-7C. In the example of FIG. 3, the control terminal of the inductor 354 is coupled to the fifth output of the control circuitry 314. As such, the control terminal of the inductor 354 is coupled to the fifth control terminal of the configurable output network 312. In the example of FIG. 3, the first terminal of the inductor 354 is coupled to the second terminal of the resistor 356 and the second current path terminal of the switch 358. Also, the second terminal of the inductor 354 is coupled to the second terminal of the inductor 348 and the supply terminal 364.

In the illustrated example of FIG. 3, the resistor 356 has a resistance of R_{WB}Ω. In the example of FIG. 3, the first terminal of the resistor 356 is coupled to the first current path terminal of the switch 358, the second terminal of the resistor 360, the second terminal of the capacitor 362, the first current path terminal of the transconductance transistor 336, and the second terminal of the cross-coupling capacitor 346. Also, the second terminal of the resistor 356 is coupled to the first terminal of the inductor 354 and the second current path terminal of the switch 358.

In the illustrated example of FIG. 3, the switch 358 is implemented by a transistor such as an FET. In the example of FIG. 3, the control terminal of the switch 358 is coupled to the sixth output of the control circuitry 314. As such, the control terminal of the switch 358 is coupled to the sixth control terminal of the configurable output network 312. In the example of FIG. 3, the first current path terminal of the switch 358 is coupled to the first terminal of the resistor 356, the second terminal of the resistor 360, the second terminal of the capacitor 362, the first current path terminal of the transconductance transistor 336, and the second terminal of the cross-coupling capacitor 346. Also, the second current path terminal of the switch 358 is coupled to the first terminal of the inductor 354 and the second terminal of the resistor 356.

In the illustrated example of FIG. 3, the resistor 360 has a resistance of up to R_{BPF}. For example, the resistor 360 is a variable resistor with a tunable resistance between zero Ω and R_{BPF}Ω. In the example of FIG. 3, the control terminal of the resistor 360 is coupled to the second output of the control circuitry 314. As such, the control terminal of the resistor 360 is coupled to the second control terminal of the configurable output network 312. In the example of FIG. 3, the first terminal of the resistor 360 is coupled to the first terminal of the resistor 350, the first current path terminal of the switch 352, the first terminal of the capacitor 362, the first current path terminal of the transconductance transistor 338, and the second terminal of the cross-coupling capacitor 344. Also, the second terminal of the resistor 360 is coupled to the first terminal of the resistor 356, the first current path terminal of the switch 358, the second terminal of the capacitor 362, the first current path terminal of the transconductance transistor 336, and the second terminal of the cross-coupling capacitor 346.

In the illustrated example of FIG. 3, the capacitor 362 has a capacitance of up to C_{BPF}. For example, the capacitor 362 is a variable capacitor with a tunable capacitance between zero F and C_{BPF} F. In the example of FIG. 3, the control terminal of the capacitor 362 is coupled to the first output of the control circuitry 314. As such, the control terminal of the capacitor 362 is coupled to the first control terminal of the configurable output network 312.

In the illustrated example of FIG. 3, the first terminal of the capacitor 362 is coupled to the first terminal of the resistor 350, the first current path terminal of the switch 352, the first terminal of the resistor 360, the first current path terminal of the transconductance transistor 338, and the second terminal of the cross-coupling capacitor 344. As such, the first terminal of the resistor 350, the first current path terminal of the switch 352, the first terminal of the resistor 360, and the first terminal of the capacitor 362 are coupled to the first terminal of the configurable output network 312. In the example of FIG. 3, the second terminal of the capacitor 362 is coupled to the first terminal of the resistor 356, the first current path terminal of the switch 358, the second terminal of the resistor 360, the first current path terminal of the transconductance transistor 336, and the second terminal of the cross-coupling capacitor 346. As such, the first terminal of the resistor 356, the first current path terminal of the switch 358, the second terminal of the resistor 360, and the second terminal of the capacitor 362 are coupled to the second terminal of the configurable output network 312.

As described above, the inductor 348 and the inductor 354 form a composite inductor with a center tap coupled to the supply terminal 364. The composite inductor (the inductor 348 and the inductor 354) is coupled between the first and second terminals of the configurable output network 312. Also, the resistor 350 is coupled between the first terminal of the configurable output network 312 and the composite inductor and the switch 352 is coupled in parallel with the resistor 350. As described above, the resistor 356 is coupled between the second terminal of the configurable output network 312 and the composite inductor and the switch 358 is coupled in parallel with the resistor 356. Also, the resistor 360 and the capacitor 362 are coupled between the first and second terminals of the configurable output network 312.

In the illustrated example of FIG. 3, at least one of the configurable input network 302 or the configurable output network 312 facilitate adjustment or configuration of the DSA 208 by the control circuitry 314 to operate in a bandpass (e.g., narrow) mode of operation or a wideband mode of operation. For example, the control circuitry 314 adjusts or configures at least one of the configurable input network 302 or the configurable output network 312 based on one or more values programmed in one or more registers. In the example of FIG. 3, when the DSA 208 is structured to operate in the narrow mode of operation, the DSA 208 can target a single frequency band that is, e.g., between 200 and 400 MHz where the center frequency is adjustable or configurable between, e.g., 1.8 GHz and 7.2 GHz. Also, when the DSA 208 is structured to operate in the narrow mode of operation, the DSA 208 may advantageously achieve an improved NF.

As described further herein, by implementing variable inductors in the configurable output network 312, the DSA 208 achieves a wide tuning range in the narrow mode of operation (for example, between 1.8 GHz and 7.2 GHz) while consuming less area on a chip than other techniques. In the example of FIG. 3, when the DSA 208 is structured to operate in the wideband mode of operation, the DSA 208 supports operating in a frequency band ranging, e.g., from 100 MHz to 6 GHz. As such, the DSA 208 can support multiple center frequencies simultaneously, for example, in scenarios where a carrier operates in multiple bands simultaneously.

In the illustrated example of FIG. 3, the high pass filter 304 may improve mitigation of noise folding when the DSA 208 is structured to operate in the wideband mode of operation. In the example of FIG. 3, the LNA 310 implements a differential common gate (CG) LNA. As described herein, the control terminal of the transconductance transistor 336 is cross-coupled with the second current path terminal of the transconductance transistor 338 via the cross-coupling capacitor 340 and the control terminal of the transconductance transistor 338 is cross-coupled with the second current path terminal of the transconductance transistor 336 via the cross-coupling capacitor 342.

Such cross-coupling increases the transconductance (gₘ) of the transconductance transistors 336, 338 by two times but may also reduce the input bandwidth of the DSA 208 by loading the second current path terminals (source terminals) of the transconductance transistors 336, 338 which may degrade the S11 parameter of an ADC coupled to the DSA 208 at higher frequencies. Advantageously, by reducing the capacitance of the cross-coupling capacitors 340, 342 from 8 C to 4 C, in some embodiments, capacitive loading at the second current path terminals of the transconductance transistors 336, 338 is reduced. Some embodiments also reduce capacitive loading by cross-coupling the transconductance transistors 336, 338 via the cross-coupling capacitors 344, 346 which have a capacitance that is one fourth the capacitance of the cross-coupling capacitors 340, 342.

For example, the first current path terminal of the transconductance transistor 338 and the control terminal of the transconductance transistor 336 are cross-coupled via the cross-coupling capacitor 344 and the first current path terminal of the transconductance transistor 336 and the control terminal of the transconductance transistor 338 are cross-coupled via the cross-coupling capacitor 346. By cross-coupling the transconductance transistors 336, 338 via the cross-coupling capacitors 344, 346, a higher amplitude voltage develops at the first current path terminals (drain terminals) than the second current path terminals (source terminals) of the transconductance transistor 336, 338.

As such, the transconductance (gₘ) of the transconductance transistors 336, 338 is increased while improving the input bandwidth and the S11 parameter of an ADC coupled to the DSA 208 (for example, at higher frequencies). For example, cross-coupling described and illustrated in connection with FIG. 3 achieves a target S11 parameter for frequencies up to 8 GHz whereas the S11 parameter for other approaches decreases (to less than −10 decibels) at frequencies greater than 4 GHz. As such, cross-coupling of the transconductance transistors 336, 338 via the cross-coupling capacitors 344, 346 improves the S11 parameter of an ADC (for example, the ADC 212) to which the DSA 208 is coupled.

Table 1 below illustrates example performance characteristics of the DSA 208 when implemented in the narrow mode operation and the wideband mode of operation, according to an embodiment of the present disclosure.

TABLE 1

| | Example | Example | | Input at | | | |
|---|---|---|---|---|---|---|---|
| | Lowest | Highest | | Maximum | | | |
| | Supported | Supported | Bandwidth | Gain | | NSD | |
| Mode of | Frequency | Frequency | (1 dB) | Setting | | dBFS/ | Example |
| operation | GHz | GHz | MHz | dBm | NF | Hz | Use Cases |
| Narrow | 1.8 | 7.2 | 400 | −13 | 4 | −154 | Low and |
| | | | | | | | mid-range |
| | | | | | | | frequency |
| | | | | | | | bands in 5G |
| | | | | | | | applications |
| | | | | | | | (L-, S-, and |
| | | | | | | | C-bands) |
| Wideband | 0.1 | 6 | Full band | −10 | 7 | −153.5 | ADCs in |
| | | | | | | | feedback |
| | | | | | | | channels and |
| | | | | | | | multi-band |
| | | | | | | | support |

In Table 1, the bandwidth column identifies the bandwidth supported by the DSA 208 when structured in the narrow mode of operation and the wideband mode of operation. In the wideband mode of operation, the DSA 208 has a bandwidth ranging from 100 MHz to 6 GHz. In the narrow mode of operation, the DSA 208 has a bandwidth of 400 MHz with the center frequency anywhere from 1.8 GHz to 7.2 GHz. Also, Table 1 identifies the input at maximum gain setting parameter in the narrow mode of operation and the wideband mode of operation. For example, the input at maximum gain setting parameter indicates the input power level in decibel (dB) milliwatts (dBm) when the gain setting for the DSA 208 is at maximum setting.

Table 1 also lists the NF, the noise spectral density (NSD), and example use cases of the DSA 208 when structured in the narrow mode of operation and the wideband mode of operation. For example, when structured in the narrow mode of operation, the DSA 208 can support 5G applications in low range and mid-range frequency bands such as the L-band (1 GHz to 2 GHz), the S-band (2 GHz to 4 GHz), and the C-band (4 GHz to 8 GHz). Also, for example, when structured in the wideband mode of operation, the DSA 208 can be utilized to sense spurious artifacts via feedback channels. When structured in the wideband mode of operation, the DSA 208 can support multi-band applications where a carrier operates in multiple bands simultaneously.

In some embodiments, control circuitry 314 may be implemented as a generic or custom processor or controlled coupled to a memory and configured to execute instructions in such memory. In some embodiments, control circuitry 314 can be implemented or include a state machine and/or a hardware accelerator. In some embodiments, control circuitry 314 may be implemented in an FPGA. In some embodiments, control circuitry controls DSA 208 in response to instructions/triggers from processor circuit 114. In some embodiments, control circuitry 314 is not capable of executing instructions from a memory. Other implementations are also possible.

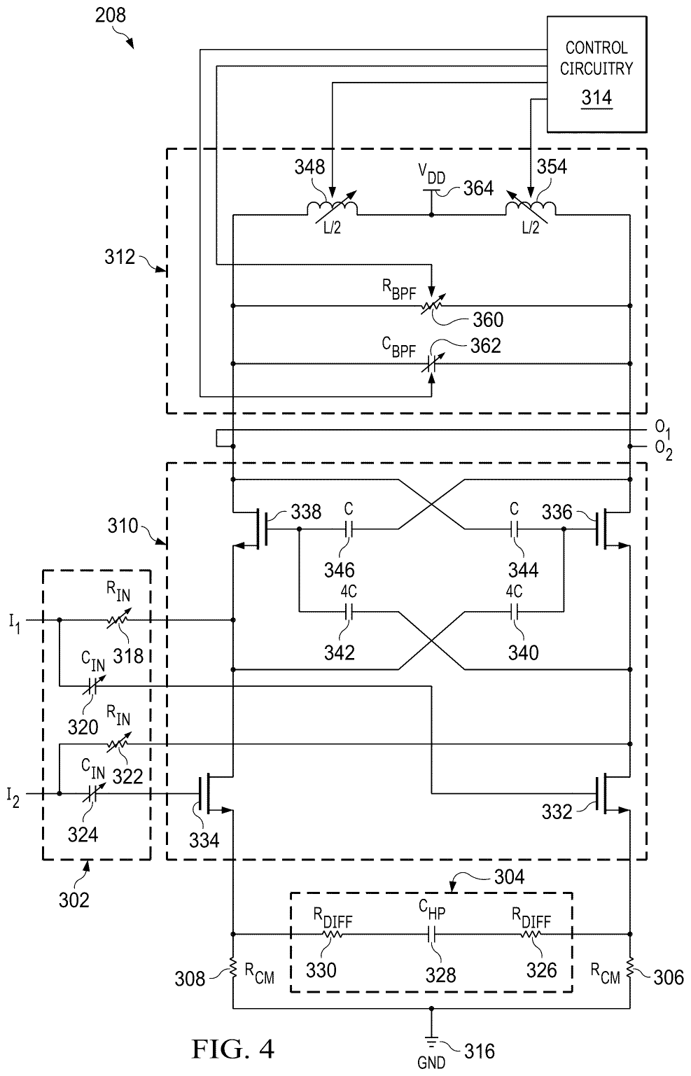

FIG. 4 is a schematic diagram of the DSA 208 of FIG. 3 when structured in a narrow mode of operation. In the example of FIG. 4, the control circuitry 314 causes the switch 352 and the switch 358 to be closed to structure the configurable output network 312, or, more generally, the DSA 208 into the narrow mode of operation. In the context of describing the state of a switch or a transistor, “closed” or “on” refers to a state when the switch or the transistor conducts current. Also, in the context of describing the state of a switch or a transistor, “open” or “off” refers to a state when the switch or the transistor does not conduct current.

In the illustrated example of FIG. 4, by causing the switch 352 and the switch 358 to be closed, the control circuitry 314 causes the configurable output network 312 to implement a tunable BPF. For example, by causing the switch 352 to be closed, the control circuitry 314 causes the first terminal of the inductor 348 to be coupled to the first terminal of the resistor 360, the first terminal of the capacitor 362, the first current path terminal of the transconductance transistor 338, and the second terminal of the cross-coupling capacitor 344, bypassing the resistor 350. Also, for example, by causing the switch 358 to be closed, the control circuitry 314 causes the first terminal of the inductor 354 to be coupled to the second terminal of the resistor 360, the second terminal of the capacitor 362, the first current path terminal of the transconductance transistor 336, and the second terminal of the cross-coupling capacitor 346, bypassing the resistor 356.

In the illustrated example of FIG. 4, by implementing a tunable BPF at the output of the DSA 208, some embodiments advantageously reduce noise aliasing and improve the NF of the DSA 208 (by 4.5 dB). For example, before an analog signal is filtered, noise may spread across the entire frequency spectrum of the analog signal. When the analog signal is sampled, the noise that is spread across the frequency spectrum is folded into the frequency band in which the analog signal is sampled. For example, the amplitude of the noise in the sampling frequency band is amplified by signal artifacts from other frequency bands as a result of sampling. As such, noise folding or noise aliasing can cause an ADC to improperly identify noise as a sample to be converted into a digital value.

For example, if an analog signal provided by a DSA has a frequency of 3.5 GHz and a sampling circuit samples the analog signal at 3 giga-samples per second (GSPS), then the sampled signal provided to an ADC will appear as a 0.5 GHz signal with noise folding from 0.5 GHz, 2.5 GHz, 3.5 GHz, 5.5 GHz, and 6.5 GHz frequency bands. Noise folding can degrade the NF of a DSA, for example, by 6 dB. To mitigate noise aliasing, some techniques implement a low-pass filter (LPF) at the output of a DSA. LPFs can operate over a large frequency range whereas other filters (such as BPFs) operate on a particular frequency band. For example, to support a large frequency range, a BPF could be implemented based on multiple inductor-capacitor (LC) tank circuits that are multiplexed together where each LC tank circuit corresponds to a different range of frequencies.

However, implementing a BPF using multiple LC tank circuits consumes a significant amount of area on a chip and is untenable for modern RF applications (for example, due to the large bandwidths across which modern RF applications are implemented). Furthermore, implementing a BPF using multiple LC tank circuits causes the supported bandwidth of the BPF and the gain of the BPF to be linked which results in reduced gain at lower frequencies. A BPF implemented based on multiple LC tank circuits also has limited tunability as only the capacitance of the LC tank circuits can be adjusted. Thus, LPFs may be utilized in applications where a large bandwidth is to be supported. In operation, an LPF removes noise appearing in the frequency spectrum of a signal when the noise is at frequencies exceeding the cutoff frequency of the LPF. As such, a significant amount of noise is still folded into the sampling frequency band of a signal depending on the frequency content of the signal.

As described herein, in the example of FIG. 4, the configurable output network 312 is structured to implement a tunable BPF using variable inductors. In some embodiments, by implementing inductors 348 and/or 354 as illustrated in of FIGS. 6A-6B or 7A-7C, the BPF implemented by the configurable output network 312 may advantageously consume significantly less arca than, for example, a BPF implemented based on multiple LC tank circuits. Also, by implementing inductors 348 and/or 354 as illustrated in FIGS. 6A-6B or 7A-7C, the BPF implemented by the configurable output network 312 may advantageously support a greater degree of tuning than, for example, a BPF implemented based on multiple LC tank circuits.

In some embodiments, the control circuitry 314 can (1) configure inductors 348 and/or 354 to shift the frequency band of the BPF implemented by the configurable output network 312 and (2) configure the capacitance of the capacitor 362 to shift the center frequency of the BPF implemented by the configurable output network 312. As such, the BPF implemented by the configurable output network 312 supports a large bandwidth (for example, 1.8 GHz to 7.2 GHz) in an arca-efficient manner. Also, by structuring the configurable output network 312 to implement a BPF at the output of the DSA 208, some embodiments may advantageously reduce the amount of noise folded into the sampling frequency band. For example, only noise present in the frequency band of the BPF, if any, may be folded into the sampling frequency band. As such, when the sampling circuit 210 samples the analog signal provided by the DSA 208, only the noise from the frequency band of the BPF may be folded into the sampling frequency band. Thus, the ADC 212 can properly distinguish between noise and samples to be converted into digital values.

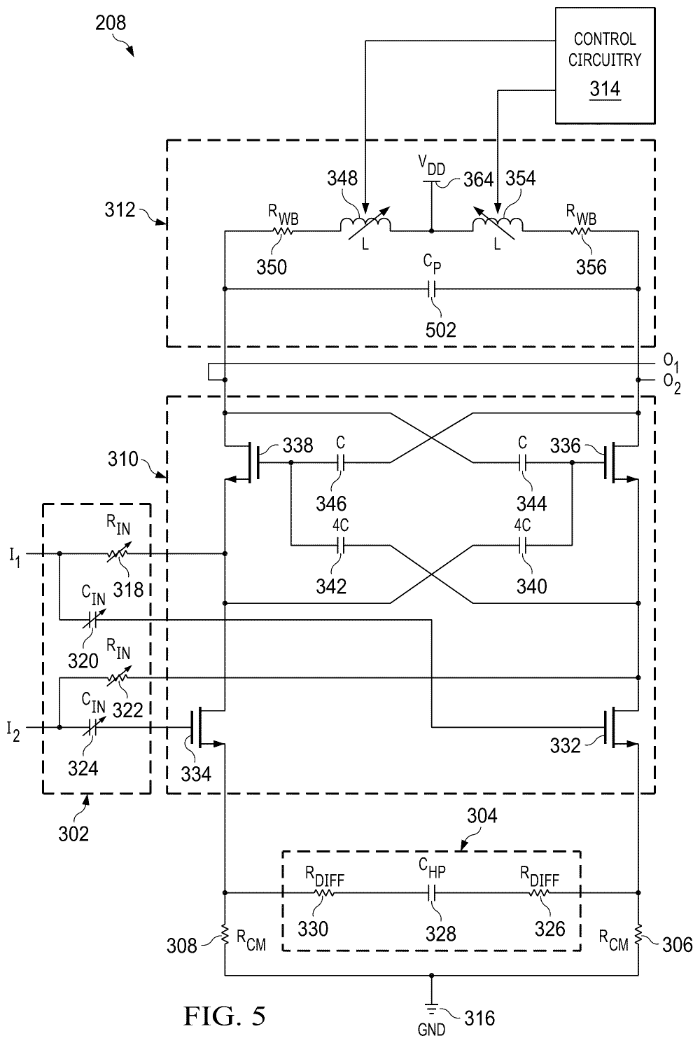

FIG. 5 is a schematic diagram of the DSA 208 of FIG. 3 when structured in a wideband mode of operation, according to an embodiment of the present disclosure. In the example of FIG. 5, the control circuitry 314 causes the switch 352 and the switch 358 to be open, sets the resistance of the resistor 360 to zero Ω, and sets the capacitance of the capacitor 362 to zero F to structure the configurable output network 312, or, more generally, the DSA 208 into the wideband mode of operation. Also, in the example of FIG. 5, an example parasitic capacitance 502 of C_{P} develops between the first terminal and the second terminal of the configurable output network 312.

In the illustrated example of FIG. 5, by causing the switch 352 and the switch 358 to be open, the control circuitry 314 effectively adds a shunt peaking load (implemented by the resistor 350 and the resistor 356) at the output of the DSA 208. By structuring the configurable output network 312 as described in FIG. 5, the control circuitry 314 causes the configurable output network 312 to implement a tunable wideband LPF. In the example of FIG. 5, the wideband LPF implemented by the configurable output network 312 may provide a flat band of frequencies (also referred to as passband), e.g., from 100 MHz to 6 GHz where the magnitude of the signal provided by the LNA 310 remains within 1 dB of an upper limit within the passband.

In the illustrated example of FIG. 5, when the configurable output network 312 is structured in the wideband mode of operation, the DSA 208 can support multi-band applications where a carrier operates in multiple bands simultaneously. For example, in a dual band scenario, an RF circuit may need to support two frequency bands for a particular communications application. As such, implementing at wideband LPF at the output of the DSA 208 facilitates support of multi-band applications by an RF circuit. Also, when the configurable output network 312 is structured in the wideband mode of operation, the DSA 208 can be utilized to sense spurious artifacts via feedback channels.

For example, in MIMO RF applications, a feedback channel is implemented to improve the ACPR between transmitters of an RF circuit. Accordingly, in MIMO RF applications, a feedback channel is implemented to facilitate DPD to correct for non-linearities in PAs of the transmitters. For example, an ADC can sense the non-linearity via a feedback channel and the sampled signal can be used to adjust coefficients used for DPD. In such examples, implementing the configurable output network 312 of the DSA 208 as a wideband LPF allows an ADC in a feedback channel to sense spurious artifacts (such as third order harmonic distortion (HD3) artifacts and third-order intermodulation distortion (IMD3) artifacts) in neighboring frequency bands.

As described herein, implementing an LPF at the output of a DSA can increase noise folding in a sampled signal. To mitigate such noise folding, the DSA 208 may implement the high pass filter 304 as described herein. For example, the high pass filter 304 filters out signals having a frequency less than 1.6 GHz to reduce the overall noise folding that occurs when sampling as well as other low frequency noise (such as flicker noise). As such, when the DSA 208 is implemented as a wideband LPF, the high pass filter 304 achieves a NF of 6 dB for the DSA 208.

Also, while implementing the configurable output network 312 as a wideband LPF allows the DSA 208 to support wideband applications such as for feedback ADCs and multi-band carriers, implementing the configurable output network 312 as a wideband LPF can slightly reduce the gain of the DSA 208 (for example, from 12.5 dB to 9.5 dB). The degradation in the NF of the DSA 208 is acceptable in such applications (for example, in feedback applications where spurious artifacts are being sensed, but control of the input level to an ADC may not be required). As illustrated in Table 1, the NSD of the DSA 208 is 7 dB when structured in the wideband mode of operation and 4 dB when structured in the narrow mode of operation. The tradeoff between the degradation in the NF (by 3 dB) and improved NSD is acceptable in wideband applications.

In the example of FIGS. 3, 4, and 5, the transistors 332, 334, 336, 338 are N-channel metal-oxide semiconductor field-effect transistors (MOSFETs). Alternatively, the transistors 332, 334, 336, 338 may be N-channel FETs, N-channel insulated-gate bipolar transistors (IGBTs), N-channel junction field effect transistors (JFETs), negative-positive-negative (NPN) bipolar junction transistors (BJTs) or, with slight modifications, positive type (P-type) equivalent devices. The transistors 332, 334, 336, 338 may be depletion mode devices, drain-extended devices, enhancement mode devices, natural transistors or other type of device structure transistors. Furthermore, the transistors 332, 334, 336, 338 may be implemented in/over a silicon (Si) substrate, a silicon carbide (SiC) substrate, a gallium nitride (GaN) substrate, or a gallium arsenide (GaAs) substrate.

FIG. 6A is a schematic diagram of a first example inductor 600 that can implement at least one of the inductors 348, 354 of FIG. 3. In the example of FIG. 6A, the inductor 600 is a four-turn inductor where the center tap of the inductor 600 is opened and the inductor 600 includes four ports (labelled P₁-N₁, P₂-N₂, P₃-N₃, and P₄-N₄). Also, the center tap of the inductor 600 is between the port labelled P₄-N₄. In the example of FIG. 6A, the inductor 600 includes two leads, labelled L₁-L₂.

In the illustrated example of FIG. 6A, the inductor 600 includes first switch 602, first connector 604, second connector 606, second switch 608, third connector 610, fourth connector 612, fifth connector 614, third switch 616, sixth connector 618, seventh connector 620, eighth connector 622, fourth switch 624, ninth connector 626, tenth connector 628, and eleventh connector 630. In the example of FIG. 6A, each of the switches 602, 608, 616, 624 has a control terminal, a first current path terminal, and a second current path terminal. Also, each of the connectors 604, 606, 610, 612, 614, 618, 620, 622, 626, 628, 630 has a first terminal and a second terminal.

In the illustrated example of FIG. 6A, each of the switches 602, 608, 616, 624 is implemented by a transistor such as an FET. Also, each of the connectors 604, 606, 610, 612, 614, 618, 620, 622, 626, 628, 630 is implemented by a conductor such as doped polysilicon or metal (copper, aluminum, etc.). In the example of FIG. 6A, the components of the inductor 600 may be implemented in various layers of a semiconductor. For example, the connectors 604, 606, the connectors 610, 614, the connectors 618, 622, and the connectors 626, 630 are implemented in (disposed in, situated in, etc.) a first metal layer of a semiconductor. Also, the connectors 612, 620, 628 are implemented in (disposed in, situated in, etc.) a second metal layer of the semiconductor. For example, the second metal layer is below the first metal layer. In some examples, the second metal layer is above the first metal layer.

In the illustrated example of FIG. 6A, the ports (P₁-N₁, P₂-N₂, P₃-N₃, and P₄-N₄) are implemented in the first metal layer of the semiconductor. Also, the switches 602, 608, 616, and 624 are implemented just below the ports (P₁-N₁, P₂-N₂, P₃-N₃, and P₄-N₄). For example, the switches 602, 608, 616, and 624 are implemented in a substrate of the semiconductor. In the example of FIG. 6A, the control terminal of the switch 602 is coupled to the control circuitry 314. For example, the control terminal of the switch 602 is connected through a top-layer metal to a supply voltage provided by the control circuitry 314. In the example of FIG. 6A, the first current path terminal of the switch 602 is coupled to the first terminal (P₁) of the first port (P₁-N₁) and the second current path terminal of the switch 602 is coupled to the second terminal (N₁) of the first port (P₁-N₁).

In the illustrated example of FIG. 6A, the first terminal of the connector 604 is coupled to the first terminal (P₁) of the first port (P₁-N₁) and the second terminal of the connector 604 is coupled to the first lead (L₁) of the inductor 600. In the example of FIG. 6A, the first terminal of the connector 606 is coupled to the second lead (L₂) of the inductor 600 and the second terminal of the connector 606 is coupled to the second terminal (N₁) of the first port (P₁-N₁). As such, the first current path terminal of the switch 602 is coupled to the first terminal of the connector 604 and the second current path terminal of the switch 602 is coupled to the second terminal of the connector 606. In the example of FIG. 6A, the connector 604 and the connector 606 are arranged in a first shape. For example, the connector 604 and the connector 606 are arranged in an octagonal shape.

In the illustrated example of FIG. 6A, the control terminal of the switch 608 is coupled to the control circuitry 314. For example, the control terminal of the switch 608 is connected through a top-layer metal to a supply voltage provided by the control circuitry 314. In the example of FIG. 6A, the first current path terminal of the switch 608 is coupled to the first terminal (P₂) of the second port (P₂-N₂) and the second current path terminal of the switch 608 is coupled to the second terminal (N₂) of the second port (P₂-N₂).

In the illustrated example of FIG. 6A, the first terminal of the connector 610 is coupled to the second terminal of the connector 612 and the second terminal of the connector 610 is coupled to the first terminal (P₂) of the second port (P₂-N₂). In the example of FIG. 6A, the first terminal of the connector 612 is coupled to the second terminal (N₁) of the first port (P₁-N₁) and the second terminal of the connector 612 is coupled to the first terminal of the connector 610. As such, the first terminal of the connector 612 is coupled to the second terminal of the connector 606. In the example of FIG. 6A, the first terminal of the connector 614 is coupled to the second terminal (N₂) of the second port (P₂-N₂) and the second terminal of the connector 614 is coupled to the first terminal (P₁) of the first port (P₁-N₁). As such, the second terminal of the connector 614 is coupled to the first terminal of the connector 604.

In the illustrated example of FIG. 6A, the first current path terminal of the switch 608 is coupled to the second terminal of the connector 610 and the second current path terminal of the switch 608 is coupled to the first terminal of the connector 614. In the example of FIG. 6A, the connector 610 and the connector 614 are arranged in a second shape concentric with the first shape. For example, the connector 610 and the connector 614 are arranged in an octagonal shape that is concentric with the octagonal shape formed by the connector 604 and the connector 606.

In the illustrated example of FIG. 6A, the control terminal of the switch 616 is coupled to the control circuitry 314. For example, the control terminal of the switch 616 is connected through a top-layer metal to a supply voltage provided by the control circuitry 314. In the example of FIG. 6A, the first current path terminal of the switch 616 is coupled to the first terminal (P₃) of the third port (P₃-N₃) and the second current path terminal of the switch 616 is coupled to the second terminal (N₃) of the third port (P₃-N₃).

In the illustrated example of FIG. 6A, the first terminal of the connector 618 is coupled to the first terminal (P₃) of the third port (P₃-N₃) and the second terminal of the connector 618 is coupled to the first terminal of the connector 620. In the example of FIG. 6A, the first terminal of the connector 620 is coupled to the second terminal of the connector 618 and the second terminal of the connector 620 is coupled to the second terminal (N₂) of the second port (P₂-N₂). As such, the second terminal of the connector 620 is coupled to the first terminal of the connector 614. In the example of FIG. 6A, the first terminal of the connector 622 is coupled to the first terminal (P₂) of the second port (P₂-N₂) and the second terminal of the connector 622 is coupled to the second terminal (N₃) of the third port (P₃-N₃).

In the illustrated example of FIG. 6A, the first current path terminal of the switch 616 is coupled to the first terminal of the connector 618 and the second current path terminal of the switch 616 is coupled to the second terminal of the connector 622. In the example of FIG. 6A, the connector 618 and the connector 622 are arranged in a third shape concentric with the second shape. For example, the connector 618 and the connector 622 are arranged in an octagonal shape that is concentric with the octagonal shape formed by the connector 610 and the connector 614.

In the illustrated example of FIG. 6A, the control terminal of the switch 624 is coupled to the control circuitry 314. For example, the control terminal of the switch 624 is connected through a top-layer metal to a supply voltage provided by the control circuitry 314. In the example of FIG. 6A, the first current path terminal of the switch 624 is coupled to the first terminal (P₄) of the fourth port (P₄-N₄) and the second current path terminal of the switch 624 is coupled to the second terminal (N₄) of the fourth port (P₄-N₄).

In the illustrated example of FIG. 6A, the first terminal of the connector 626 is coupled to the second terminal of the connector 628 and the second terminal of the connector 626 is coupled to the first terminal (P₄) of the fourth port (P₄-N₄). In the example of FIG. 6A, the first terminal of the connector 628 is coupled to the second terminal (N₃) of the third port (P₃-N₃) and the second terminal of the connector 628 is coupled to the first terminal of the connector 626. As such, the first terminal of the connector 628 is coupled to the second terminal of the connector 622. In the example of FIG. 6A, the first terminal of the connector 630 is coupled to the second terminal (N₄) of the fourth port (P₄-N₄) and the second terminal of the connector 630 is coupled to the first terminal (P₃) of the third port (P₃-N₃). As such, the second terminal of the connector 630 is coupled to the first terminal of the connector 618.

In the illustrated example of FIG. 6A, the first current path terminal of the switch 624 is coupled to the second terminal of the connector 626 and the second current path terminal of the switch 624 is coupled to the first terminal of the connector 630. In the example of FIG. 6A, the connector 626 and the connector 630 are arranged in a fourth shape concentric with the third shape. For example, the connector 626 and the connector 630 are arranged in an octagonal shape that is concentric with the octagonal shape formed by the connector 618 and the connector 622.

In the illustrated example of FIG. 6A, the inductor 600 can be arranged into four different arrangements that have four different inductances. For example, depending on which of the switches 602, 608, 616, 624 are configured to be closed (by the control circuitry 314), the inductor 600 can be configured into the four different arrangements. In the example of FIG. 6A, the four different arrangements have inductances of 0.6 nanohenries (nH), 1.4 nH, 2.5 nH, and 3.6 nH. As such, the inductor 600 can be tuned based on an application in which the DSA 208 is implemented.

For example, setting different inductance values for the inductor 600 allows a user to tune the center frequency of the passband (for example, from 1.8 GHz to 7.2 GHz) when the configurable output network 312 is implemented as a BPF. Also, when the configurable output network 312 is implemented as a wideband LPF, a user can tune the cutoff frequency of the wideband LPF by adjusting the inductance of the inductor 600. For example, when the configurable output network 312 is implemented as a wideband LPF, the inductance of the inductor 600 is set (by the control circuitry 314) to 1.4 nH to achieve a passband from 100 MHz to 6 GHz.

As illustrated in the example of FIG. 6A, for a four-turn inductor coil, four different inductance values can be achieved for the inductor 600. Accordingly, depending on which of the switches 602, 608, 616, and 624 are configured to be closed (by the control circuitry 314), the inductor 600 can be configured into four different arrangements having different inductances. More generally, for an N-turn inductor coil, N different inductance values can be achieved for the inductor. As such, examples described herein include a programmable inductor that achieves tunable passbands in a manner that consumes less area than other approaches. For example, as described herein, a BPF can be implemented based on multiple LC tank circuits that are multiplexed together where each LC tank circuit corresponds to a different range of frequencies. Implementing tunable passbands utilizing multiple LC tanks circuits consumes at least three to four times more area than implementing tunable passbands based on the inductor 600 of FIG. 6A.

FIG. 6B is a cross-sectional view illustrating how the switch 624 is coupled to the connectors 626, 630 of the first metal layer of the semiconductor. For example in FIG. 6B, the inductor 600 is implemented in an example semiconductor 632 having ten metal layers, a top-layer metal, and a substrate. In the example of FIG. 6B, the connectors 604, 606, 610, 614, 618, 622, 626, 630 are implemented in the top-layer metal of the semiconductor 632 and the connectors 612, 620, 628 (not illustrated) are implemented in the metal layer just below the top-layer metal of the semiconductor 632. In the example of FIG. 6B, the fourth port (P₄-N₄) is implemented in the top-layer metal of the semiconductor 632.

In the illustrated example of FIG. 6B, the switch 624 is implemented in the substrate of the semiconductor 632 and is connected to the connectors 626, 630 by vias through the metal layers of the semiconductor 632. For example, the first current path terminal of the switch 624 is coupled to the first terminal (P₄) of the fourth port (P₄-N₄) and the second current path terminal of the switch 624 is coupled to the second terminal (N₄) of the fourth port (P₄-N₄). In the example of FIG. 6B, the control terminal of the switch 624 is connected to a supply voltage provided by the control circuitry 314 by vias through the top-layer metal of the semiconductor 632.

In examples described herein, the switch 616 is coupled to the connectors 618, 622 in a similar manner as the switch 624 is coupled to the connectors 626, 630. In examples described herein, the switch 608 is coupled to the connectors 610, 614 in a similar manner as the switch 624 is coupled to the connectors 626, 630. In examples described herein, the switch 602 is coupled to the connectors 604, 606 in a similar manner to the switch 624 is coupled to the connectors 626, 630.

FIG. 7A is a schematic diagram of a second example inductor 700 that can implement at least one of the inductors 348, 354 of FIG. 3, according to an embodiment of the present disclosure. In the example of FIG. 7A, the inductor 700 is a four-turn inductor implemented in two layers of a semiconductor and the inductor 700 includes four ports (labelled P₁-N₁, P₂-N₂, P₃-N₃, and P₄-N₄). Also, in the example of FIG. 7A, the inductor 700 includes two leads, labelled L₁-L₂.

In the illustrated example of FIG. 7A, the inductor 700 includes first switch 702, first connector 704, second connector 706, second switch 708, third connector 710, fourth connector 712, fifth connector 714, third switch 716, sixth connector 718, seventh connector 720, eighth connector 722, fourth switch 724, ninth connector 726, and tenth connector 728. In the example of FIG. 7A, each of the switches 702, 708, 716, 724 has a control terminal, a first current path terminal, and a second current path terminal. Also, each of the connectors 704, 706, 710, 712, 714, 718, 720, 722, 726, 728 has a first terminal and a second terminal.

In the illustrated example of FIG. 7A, each of the switches 702, 708, 716, 724 is implemented by a transistor such as an FET. Also, each of the connectors 704, 706, 710, 712, 714, 718, 720, 722, 726, 728 is implemented by a conductor such as doped polysilicon or metal (copper, aluminum, etc.). In the example of FIG. 7A, the components of the inductor 700 may be implemented in various layers of a semiconductor. For example, the connectors 704, 706, the connectors 710, 714, and the connector 720 are implemented in (disposed in, situated in, etc.) a first metal layer of a semiconductor. Also, the connector 712, the connectors 718, 722, and the connectors 726, 728 are implemented in (disposed in, situated in, etc.) a second metal layer of the semiconductor. For example, the second metal layer is below the first metal layer. In some examples, the second metal layer is above the first metal layer.

In the illustrated example of FIG. 7A, the ports (P₁-N₁ and P₂-N₂) are implemented in the first metal layer of the semiconductor. Also, the switches 702 and 708 are implemented below the ports (P₁-N₁ and P₂-N₂). For example, the switches 702 and 708 are implemented in a substrate of the semiconductor. In the example of FIG. 7A, the ports (P₃-N₃, and P₄-N₄) are implemented in the second metal layer of the semiconductor. Also, the switches 716 and 724 are implemented below the ports (P₃-N₃ and P₄-N₄). For example, the switches 716 and 724 are implemented in a substrate of the semiconductor. In the example of FIG. 7A, the control terminal of the switch 702 is coupled to the control circuitry 314. For example, the control terminal of the switch 702 is connected through a top-layer metal to a supply voltage provided by the control circuitry 314. In the example of FIG. 7A, the first current path terminal of the switch 702 is coupled to the first terminal (P₁) of the first port (P₁-N₁) and the second current path terminal of the switch 702 is coupled to the second terminal (N₁) of the first port (P₁-N₁).

In the illustrated example of FIG. 7A, the first terminal of the connector 704 is coupled to the first terminal (P₁) of the first port (P₁-N₁) and the second terminal of the connector 704 is coupled to the first lead (L₁) of the inductor 700. In the example of FIG. 7A, the first terminal of the connector 706 is coupled to the second lead (L₂) of the inductor 700 and the second terminal of the connector 706 is coupled to the second terminal (N₁) of the first port (P₁-N₁). As such, the first current path terminal of the switch 702 is coupled to the first terminal of the connector 704 and the second current path terminal of the switch 702 is coupled to the second terminal of the connector 706. In the example of FIG. 7A, the connector 704 and the connector 706 are arranged in a first shape. For example, the connector 704 and the connector 706 are arranged in an octagonal shape.

In the illustrated example of FIG. 7A, the control terminal of the switch 708 is coupled to the control circuitry 314. For example, the control terminal of the switch 708 is connected through a top-layer metal to a supply voltage provided by the control circuitry 314. In the example of FIG. 7A, the first current path terminal of the switch 708 is coupled to the first terminal (P₂) of the second port (P₂-N₂) and the second current path terminal of the switch 708 is coupled to the second terminal (N₂) of the second port (P₂-N₂).

In the illustrated example of FIG. 7A, the first terminal of the connector 710 is coupled to the second terminal of the connector 712 and the second terminal of the connector 710 is coupled to the first terminal (P₂) of the second port (P₂-N₂). In the example of FIG. 7A, the first terminal of the connector 712 is coupled to the second terminal (N₁) of the first port (P₁-N₁) and the second terminal of the connector 712 is coupled to the first terminal of the connector 710. As such, the first terminal of the connector 712 is coupled to the second terminal of the connector 706. In the example of FIG. 7A, the first terminal of the connector 714 is coupled to the second terminal (N₂) of the second port (P₂-N₂) and the second terminal of the connector 714 is coupled to the first terminal (P₁) of the first port (P₁-N₁). As such, the second terminal of the connector 714 is coupled to the first terminal of the connector 704.

In the illustrated example of FIG. 7A, the first current path terminal of the switch 708 is coupled to the second terminal of the connector 710 and the second current path terminal of the switch 708 is coupled to the first terminal of the connector 714. In the example of FIG. 7A, the connector 710 and the connector 714 are arranged in a second shape concentric with the first shape. For example, the connector 710 and the connector 714 are arranged in an octagonal shape that is concentric with the octagonal shape formed by the connector 704 and the connector 706.

In the illustrated example of FIG. 7A, the control terminal of the switch 716 is coupled to the control circuitry 314. For example, the control terminal of the switch 716 is connected through a top-layer metal to a supply voltage provided by the control circuitry 314. In the example of FIG. 7A, the first current path terminal of the switch 716 is coupled to the first terminal (P₃) of the third port (P₃-N₃) and the second current path terminal of the switch 716 is coupled to the second terminal (N₃) of the third port (P₃-N₃).

In the illustrated example of FIG. 7A, the first terminal of the connector 718 is coupled to the first terminal (P₃) of the third port (P₃-N₃) and the second terminal of the connector 718 is coupled to the second terminal (N₂) of the second port (P₂-N₂). For example, the second terminal of the connector 718 is coupled to the first terminal of the connector 714. In the example of FIG. 7A, the first terminal of the connector 720 is coupled to the second terminal of the connector 728 and the second terminal of the connector 720 is coupled to the first terminal (P₃) of the third port (P₃-N₃). For example, the second terminal of the connector 720 is coupled to the first terminal of the connector 718. In the example of FIG. 7A, the first terminal of the connector 722 is coupled to the first terminal (P₂) of the second port (P₂-N₂) and the second terminal of the connector 722 is coupled to the second terminal (N₃) of the third port (P₃-N₃). For example, the first terminal of the connector 722 is coupled to the second terminal of the connector 710.

In the illustrated example of FIG. 7A, the first current path terminal of the switch 716 is coupled to the first terminal of the connector 718 and the second current path terminal of the switch 716 is coupled to the second terminal of the connector 722. In the example of FIG. 7A, the connector 718 and the connector 722 are arranged in a third shape concentric with and substantially aligned to the second shape. For example, the connector 718 and the connector 722 are arranged in an octagonal shape that is concentric with and substantially aligned to the octagonal shape formed by the connector 710 and the connector 714.

In the illustrated example of FIG. 7A, the control terminal of the switch 724 is coupled to the control circuitry 314. For example, the control terminal of the switch 724 is connected through a top-layer metal to a supply voltage provided by the control circuitry 314. In the example of FIG. 7A, the first current path terminal of the switch 724 is coupled to the first terminal (P₄) of the fourth port (P₄-N₄) and the second current path terminal of the switch 724 is coupled to the second terminal (N₄) of the fourth port (P₄-N₄).

In the illustrated example of FIG. 7A, the first terminal of the connector 726 is coupled to the second terminal (N₃) of the third port (P₃-N₃) and the second terminal of the connector 726 is coupled to the first terminal (P₄) of the fourth port (P₄-N₄). For example, the first terminal of the connector 726 is coupled to the second terminal of the connector 722. In the example of FIG. 7A, the first terminal of the connector 728 is coupled to the second terminal (N₄) of the fourth port (P₄-N₄) and the second terminal of the connector 728 is coupled to the first terminal of the connector 720.

In the illustrated example of FIG. 7A, the first current path terminal of the switch 724 is coupled to the second terminal of the connector 726 and the second current path terminal of the switch 724 is coupled to the first terminal of the connector 728. In the example of FIG. 7A, the connector 726 and the connector 728 are arranged in a fourth shape concentric with and substantially aligned to the first shape. For example, the connector 726 and the connector 728 are arranged in an octagonal shape that is concentric with and substantially aligned to the octagonal shape formed by the connector 704 and the connector 706.

As illustrated in FIG. 7A, the inductor 700 is a four-turn inductor implemented in two layers. For example, a first turn is formed in the first metal layer of the semiconductor by the connectors 704, 714, a second turn is formed in the second metal layer of the semiconductor by the connectors 718, 728 (connected by the connector 720 in the first metal layer), a third turn is formed in the second metal layer by the connectors 726, 722, and a fourth turn is formed in the first metal layer by the connectors 710, 706 (connected by the connector 712 in the second metal layer). Thus, the inductor 700 can be arranged into four different arrangements that have four different inductances depending on which of the switches 702, 708, 716, 724 are configured to be closed (by the control circuitry 314). In the example of FIG. 7A, the inductor 700 may decrease the area consumed by a four-turn inductor by about 62% as compared to the inductor 600. For example, the inductor 600 consumes an area of 0.0676 square millimeters (mm²) and the inductor 700 consumes an area of 0.0256 mm².

FIG. 7B is a cross-sectional view illustrating how the switch 708 is coupled to the connectors 710, 714 of the first metal layer of the semiconductor. For example in FIG. 7B, the inductor 700 is implemented in an example semiconductor 730 having ten metal layers, a top-layer metal, and a substrate. In the example of FIG. 7B, the connectors 704, 706, 710, 714 are implemented in the top-layer metal of the semiconductor 730 and the connectors 718, 722, 726, 728 are implemented in the metal layer just below the top-layer metal of the semiconductor 730. In the example of FIG. 7B, the second port (P₂-N₂) is implemented in the top-layer metal of the semiconductor 730.

In the illustrated example of FIG. 7B, the switch 708 is implemented in the substrate of the semiconductor 730 and is connected to the connectors 710, 714 by vias through the metal layers of the semiconductor 730. For example, the first current path terminal of the switch 708 is coupled to the first terminal (P₂) of the second port (P₂-N₂) and the second current path terminal of the switch 708 is coupled to the second terminal (N₂) of the second port (P₂-N₂). In the example of FIG. 7B, the control terminal of the switch 708 is connected to a supply voltage provided by the control circuitry 314 by vias through the top-layer metal of the semiconductor 730. In examples described herein, the switch 702 is coupled to the connectors 704, 706 in a similar manner as the switch 708 is coupled to the connectors 710, 714.

FIG. 7C is a cross-sectional view illustrating how the switch 716 is coupled to the connectors 718, 722 of the second metal layer of the semiconductor, according to an embodiment of the present disclosure. For example in FIG. 7C, the inductor 700 is implemented in the semiconductor 730. In the example of FIG. 7C, the third port (P₃-N₃) is implemented in the metal layer just below the top-layer metal of the semiconductor 730. In the example of FIG. 7C, the switch 716 is implemented in the substrate of the semiconductor 730 and is connected to the connectors 718, 722 by vias through the metal layers of the semiconductor 730. For example, the first current path terminal of the switch 716 is coupled to the first terminal (P₃) of the third port (P₃-N₃) and the second current path terminal of the switch 716 is coupled to the second terminal (N₃) of the third port (P₃-N₃). In the example of FIG. 7C, the control terminal of the switch 716 is connected to a supply voltage provided by the control circuitry 314 by vias through the top-layer metal of the semiconductor 730. In examples described herein, the switch 724 is coupled to the connectors 726, 728 in a similar manner as the switch 716 is coupled to the connectors 718, 722.

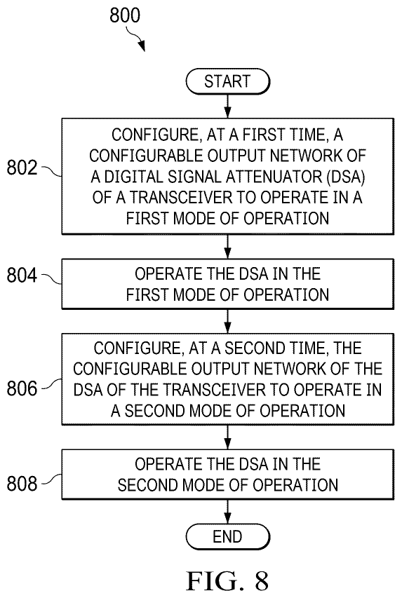

FIG. 8 illustrates a flowchart of embodiment method 800 for operating a DSA, such as DSA 300, according to an embodiment of the present disclosure. Method 800 may be implemented, e.g., by control circuitry 314. Method 800 begin at block 802, at which the control circuitry 314 configures, at a first time, the configurable output network 312 of the DSA 208 to operate in a first mode of operation. In the example of FIG. 8, the first mode of operation is a wideband mode of operation. For example, at block 802, the control circuitry 314 opens the switch 352 and the switch 358, sets respective inductances of the inductor 348 and the inductor 354, and disables the resistor 360 and the capacitor 362. By opening the switch 352 and the switch 358, setting respective inductances of the inductor 348 and the inductor 354, and disabling the resistor 360 and the capacitor 362, the control circuitry 314 operates the configurable output network 312 of the DSA 208 as a low-pass filter in the first mode of operation. At block 804, the control circuitry 314 operates the DSA 208 in the first mode of operation.

In the illustrated example of FIG. 8, at block 806, the control circuitry 314 configures, at a second time, the configurable output network 312 of the DSA 208 to operate in a second mode of operation. For example, the second time is after the first time. In the example of FIG. 8, the second mode of operation is a narrowband mode of operation. For example, at block 806, the control circuitry 314 closes the switch 352 and the switch 358, sets respective inductances of the inductor 348 and the inductor 354, sets a resistance of the resistor 360, and sets a capacitance of the capacitor 362. By closing the switch 352 and the switch 358, setting respective inductances of the inductor 348 and the inductor 354, setting a resistance of the resistor 360, and setting a capacitance of the capacitor 362, the control circuitry 314 operates the configurable output network 312 of the DSA 208 as a bandpass filter in the second mode of operation. At block 808, the control circuitry 314 operates the DSA 208 in the second mode of operation.

In some examples, the first mode of operation is a narrowband mode of operation. In such examples, the control circuitry 314 closes the switch 352 and the switch 358, sets respective inductances of the inductor 348 and the inductor 354, sets a resistance of the resistor 360, and sets a capacitance of the capacitor 362 to place the configurable output network 312 in the narrowband mode of operation. As such, the control circuitry 314 operates the configurable output network 312 of the DSA 208 as a bandpass filter in the first mode of operation.

In examples where the first mode of operation is a narrowband mode of operation, the second mode of operation includes the wideband mode of operation. In such examples, the control circuitry 314 opens the switch 352 and the switch 358, sets respective inductances of the inductor 348 and the inductor 354, and disables the resistor 360 and the capacitor 362. As such, the control circuitry 314 operates the configurable output network 312 of the DSA 208 as a low-pass filter in the second mode of operation.

While an example manner of implementing the control circuitry 314 of FIG. 3 is illustrated in FIG. 3, one or more of the elements, processes, or devices illustrated in FIG. 3 may be combined, divided, re-arranged, omitted, eliminated, or implemented in any other way. Further, the example control circuitry 314 of FIG. 3, may be implemented by hardware alone or by hardware in combination with software and firmware. Thus, for example, the control circuitry 314 of FIG. 3, could be implemented by programmable circuitry in combination with one or more machine-readable instructions (for example, firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example control circuitry 314 of FIG. 3 may include one or more elements, processes, or devices in addition to, or instead of, those illustrated in FIG. 3, or may include more than one of any or all of the illustrated elements, processes and devices.

Flowchart(s) representative of steps, which may be executed by programmable circuitry to at least one of implement or instantiate the control circuitry 314 of FIG. 3 or representative of example operations which may be performed by programmable circuitry to at least one of implement or instantiate the control circuitry 314 of FIG. 3, are shown in FIG. 8. If the steps are implemented as machine-readable instructions, the machine-readable instructions may be one or more executable programs or portion(s) of one or more executable programs for execution by programmable circuitry, such as a generic or custom processor. In some embodiments, one or more function(s) or portion(s) of functions to be performed by the programmable circuitry (for example, an FPGA).

As mentioned herein, the example operations of FIG. 8 may be implemented using executable instructions (for example, at least one of computer-readable or machine-readable instructions) stored on one or more non-transitory computer-readable or machine-readable media. As used herein, the terms non-transitory computer-readable medium, non-transitory computer-readable storage medium, non-transitory machine-readable medium, and non-transitory machine-readable storage medium are expressly defined to include any type of computer-readable storage device or storage disk and to exclude propagating signals and to exclude transmission media. Examples of such non-transitory computer-readable medium, non-transitory computer-readable storage medium, non-transitory machine-readable medium, or non-transitory machine-readable storage medium include flash memory, registers and/or flip-flops, read-only memory (ROM), etc.

Circuits described herein may be reconfigurable to include a replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated.

As used herein, “approximately,” “about,” and “substantially” modify their subjects/values to recognize the potential presence of variations that occur in real world applications. For example, “approximately,” “about,” and “substantially” may modify dimensions or positions that may not be exact due to at least one of manufacturing tolerances or other real-world imperfections. For example, “approximately,” “about,” and “substantially” may indicate such dimensions or positions may be within a tolerance range of +/−10% unless otherwise specified herein, or, if the value is zero, a reasonable range of values around zero.

Modifications are possible in the described examples, and other examples are possible, within the scope of the claims.

From the foregoing, it will be appreciated that example systems, apparatus, articles of manufacture, and methods have been described for a highly adjustable, compact DSA for RF sampling ADCs. For example, described systems, apparatus, articles of manufacture, and methods include a programmable inductor that provides a wide tuning range and facilitates implementing a bandpass filter and a wideband low-pass filter at the output of a DSA. As such, described examples include a highly adjustable analog front end that can cater to a wide range of applications. For example, by implementing a bandpass filter at the output of a DSA and a noise cancelling LNA, examples described herein reduce the noise figure of the DSA, for example, from 8 dB to 4 dB.

Also, for example, by partially cross-coupling transconductance transistors of the LNA from the drain to gate, examples described herein significantly improve the S11 parameter of a DSA across frequencies. In dual-band applications or feedback ADC applications, examples described herein implement a very wideband low-pass filter at the output of the DSA. Also, by including a HPF at the common source of the configurable input network of a DSA, examples described herein reduce low frequency noise folding and therefore improve the noise figure, for example, by another 0.5 dB, in the wideband mode of operation. In examples described herein, the same inductor(s) are utilized in both a narrow mode of operation and a wideband mode of operation. As such, examples described herein reduce the amount of area consumed by a tunable DSA.

As described herein, example systems, apparatus, articles of manufacture, and methods include a highly configurable DSA having (1) a reconfigurable output network supporting a narrow mode of operation and a wideband mode of operation, (2) cross-coupled transistors to improve the S11 parameter of the DSA across frequency, and (3) a high pass filter (HPF) to block frequency aliasing when the DSA is structured in the wideband mode of operation. Described systems, apparatus, articles of manufacture, and methods improve the efficiency of using a computing device by reducing the area to implement a tunable DSA, increasing the range of tuning of the DSA, and supporting both a narrow mode of operation and a wideband mode operation with the one circuit. Described systems, apparatus, articles of manufacture, and methods are also directed to one or more improvement(s) in the operation of a machine such as a computer or other electronic, electromechanical, or mechanical device.

Example embodiments of the present disclosure are summarized here. Other embodiments can also be understood from the entirety of the specification and the claims filed herein.

Example 1. An electronic circuit including: an amplifier having first and second outputs, first and second inputs, and first and second terminals; a high pass filter coupled between the first and second terminals of the amplifier; and a configurable output network coupled between the first and second outputs of the amplifier.

Example 2. The electronic circuit of example 1, where the amplifier includes: a first transistor having a control terminal coupled to the first input of the amplifier, a first current path terminal coupled to the first output of the amplifier, and a second current path terminal coupled to the first terminal of the amplifier; a second transistor having a control terminal coupled to the second input of the amplifier, a first current path terminal coupled to the second output of the amplifier, and a second current path terminal coupled to the second terminal of the amplifier; a third transistor having a first current path terminal coupled to the first output of the amplifier, and a second current path terminal coupled to the first current path terminal of the first transistor; and a fourth transistor having a first current path terminal coupled to the second output of the amplifier, and a second current path terminal coupled to the first current path terminal of the second transistor.

Example 3. The electronic circuit of one of examples 1 or 2, further including: a first capacitor coupled between the control terminal of the third transistor and the first current path terminal of the fourth transistor; a second capacitor coupled between the control terminal of the third transistor and the second current path terminal of the fourth transistor; a third capacitor coupled between the control terminal of the fourth transistor and the first current path terminal of the third transistor; and a fourth capacitor coupled between the control terminal of the fourth transistor and the second current path terminal of the third transistor.

Example 4. The electronic circuit of one of examples 1 to 3, where the high pass filter includes: a first capacitor coupled between the first terminal of the amplifier and the second terminal of the amplifier; a first resistor coupled between the first terminal of the amplifier and the first capacitor; and a second resistor coupled between the second terminal of the amplifier and the first capacitor.

Example 5. The electronic circuit of one of examples 1 to 4, further including: a first resistor coupled between the first terminal of the amplifier and ground; and a second resistor coupled between the second terminal of the amplifier and ground.

Example 6. The electronic circuit of one of examples 1 to 5, further including a configurable input network having: a first output coupled to the second current path terminal of the third transistor; a second output coupled to the second current path terminal of the fourth transistor; a third output coupled to the control terminal of the first transistor; and a fourth output coupled to the control terminal of the second transistor.

Example 7. The electronic circuit of one of examples 1 to 6, where the configurable input network includes: first and second inputs; a first resistor coupled between the first input of the configurable input network and the second current path terminal of the third transistor; a first capacitor coupled between the first input of the configurable input network and the control terminal of the second transistor; a second resistor coupled between the second input of the configurable input network and the second current path terminal of the fourth transistor; and a second capacitor coupled between the second input of the configurable input network and the control terminal of the first transistor.

Example 8. The electronic circuit of one of examples 1 to 7, where each of the first and second resistors has a configurable resistance, and each of the first and second capacitors has a configurable capacitance.

Example 9. The electronic circuit of one of examples 1 to 8, where the configurable output network includes an inductor coupled between the first and second outputs of the amplifier.

Example 10. The electronic circuit of one of examples 1 to 9, where the inductor includes: a first metal layer disposed above a semiconductor substrate; a second metal layer disposed above the semiconductor substrate; a third switch having a first terminal and a second terminal; a first connector disposed in the first metal layer and coupled to the first terminal of the third switch; a second connector disposed in the first metal layer and coupled to the second terminal of the third switch, the first connector and the second connector arranged in a first shape; a fourth switch having a first terminal and a second terminal; a third connector disposed in the first metal layer and coupled to the first terminal of the fourth switch; a fourth connector disposed in the second metal layer and coupled to the third connector and the second terminal of the third switch; and a fifth connector disposed in the first metal layer and coupled to the second terminal of the fourth switch and the first terminal of the third switch, the third connector and the fifth connector arranged in a second shape concentric with the first shape.

Example 11. The electronic circuit of one of examples 1 to 10, where the inductor includes: a first metal layer disposed above a semiconductor substrate; a second metal layer disposed above the semiconductor substrate; a third switch having a first terminal and a second terminal; a first connector disposed in the first metal layer and coupled to the first terminal of the third switch; a second connector disposed in the first metal layer and coupled to the second terminal of the third switch, the first connector and the second connector arranged in a first shape; a fourth switch having a first terminal and a second terminal; a third connector disposed in the second metal layer and coupled to the first terminal of the fourth switch and the second terminal of the third switch; and a fourth connector disposed in the second metal layer and coupled to the second terminal of the fourth switch and the first terminal of the third switch, the third connector and the fourth connector arranged in a second shape concentric with and substantially aligned to the first shape.

Example 12. The electronic circuit of one of examples 1 to 11, where the configurable output network includes: a first resistor coupled between the first output of the amplifier and the inductor; and a second resistor coupled between the second output of the amplifier and the inductor.

Example 13. The electronic circuit of one of examples 1 to 12, where the configurable output network includes: a first switch coupled in parallel with the first resistor; and a second switch coupled in parallel with the second resistor.

Example 14. The electronic circuit of one of examples 1 to 13, where the configurable output network includes: a variable resistor coupled between the first and second outputs of the amplifier; and a variable capacitor coupled between the first and second outputs of the amplifier.

Example 15. The electronic circuit of one of examples 1 to 14, where the configurable output network includes: a first variable inductor having a first terminal and a second terminal, the second terminal of the first variable inductor coupled to a supply terminal; a first resistor having a first terminal coupled to the first output of the amplifier and a second terminal coupled to the first terminal of the first variable inductor; a first switch coupled in parallel with the first resistor; a second variable inductor having a first terminal and a second terminal, the second terminal of the second variable inductor coupled to the supply terminal; a second resistor having a first terminal coupled to the second output of the amplifier and a second terminal coupled to the first terminal of the second variable inductor; a second switch coupled in parallel with the second resistor; a variable resistor coupled between the first and second outputs of the amplifier; and a variable capacitor coupled between the first and second outputs of the amplifier.

Example 16. The electronic circuit of one of examples 1 to 15, including control circuitry configured to: in a first mode, close the first switch and second switches; and in a second mode, open the first and second switches.

Example 17. The electronic circuit of one of examples 1 to 16, where the configurable input network, the amplifier, the high pass filter, and the configurable output network form a digital signal attenuator (DSA) having first and second outputs and first and second inputs, the electronic circuit including: a balun circuit having first and second outputs and an input; a matching network having first and second outputs coupled to the first and second inputs of the DSA, respectively, and first and second inputs coupled to the first and second outputs of the balun circuit, respectively; a sampling circuit having first and second outputs and first and second inputs coupled to the first and second outputs of the DSA, respectively; and an analog-to-digital converter (ADC) having first and second inputs coupled to the first and second outputs of the sampling circuit, respectively.

Example 18. An integrated circuit including: a semiconductor substrate; a first metal layer disposed above the semiconductor substrate; a second metal layer disposed above the semiconductor substrate; a first switch having a first terminal and a second terminal; a first connector disposed in the first metal layer and coupled to the first terminal of the first switch; a second connector disposed in the first metal layer and coupled to the second terminal of the first switch, the first connector and the second connector arranged in a first shape; a second switch having a first terminal and a second terminal; a third connector disposed in the second metal layer and coupled to the first terminal of the second switch and the second terminal of the first switch; and a fourth connector disposed in the second metal layer and coupled to the second terminal of the second switch and the first terminal of the first switch, the third connector and the fourth connector arranged in a second shape concentric with and substantially aligned to the first shape.

Example 19. The integrated circuit of example 18, where the first switch, the first connector, the second connector, the second switch, the third connector, and the fourth connector form a first variable inductor or a second variable inductor, the at least one of the first variable inductor or the second variable inductor including: a third switch having a first terminal and a second terminal, the first terminal coupled to the second connector; a fifth connector disposed in the second metal layer and coupled to the second terminal of the third switch and the first connector; a sixth connector disposed in the first metal layer and coupled to the first terminal of the third switch; and a seventh connector disposed in the first metal layer and coupled to the second terminal of the third switch, the sixth connector and the seventh connector arranged in a third shape concentric with the first shape.

Example 20. The integrated circuit of one of examples 18 or 19, where the at least one of the first variable inductor or the second variable inductor includes: a fourth switch having a first terminal and a second terminal; an eighth connector disposed in the second metal layer and coupled to the first terminal of the fourth switch and the second terminal of the second switch; a ninth connector disposed in the first metal layer and coupled to the first terminal of the second switch; and a tenth connector disposed in the second metal layer and coupled to the second terminal of the fourth switch and the ninth connector, the eighth connector and the tenth connector arranged in a fourth shape concentric with and substantially aligned to the third shape.

Example 21. The integrated circuit of one of examples 18 to 20, the first switch, the first connector, the second connector, the second switch, the third connector, and the fourth connector form at least one of a first variable inductor or a second variable inductor, and the integrated circuit includes: the first variable inductor, the first variable inductor having a first terminal and a second terminal coupled to a supply terminal; a first resistor having a first terminal and a second terminal coupled to the first terminal of the first variable inductor; a third switch having a first terminal coupled to the first terminal of the first resistor and a second terminal coupled to the first terminal of the first variable inductor; the second variable inductor, the second variable inductor having a first terminal and a second terminal coupled to the supply terminal; a second resistor having a first terminal and a second terminal coupled to the first terminal of the second variable inductor; a fourth switch having a first terminal coupled to the first terminal of the second resistor and a second terminal coupled to the first terminal of the second variable inductor; a variable resistor having a first terminal coupled to the first terminal of the first resistor and a second terminal coupled to the first terminal of the second resistor; and a variable capacitor having a first terminal coupled to the first terminal of the first resistor and a second terminal coupled to the first terminal of the second resistor.

Example 22. The integrated circuit of one of examples 18 to 21, including: a first transistor having a control terminal, a first current path terminal, and a second current path terminal; a second transistor having a control terminal, a first current path terminal, and a second current path terminal; a third transistor having a control terminal, a first current path terminal, and a second terminal, the first terminal coupled to the first terminal of the first resistor; a fourth transistor having a control terminal, a first current path terminal, and a second current path terminal, the first current path terminal coupled to the first terminal of the second resistor; a first capacitor coupled between the control terminal of the third transistor and the first current path terminal of the fourth transistor; a second capacitor coupled between the control terminal of the third transistor and the second current path terminal of the fourth transistor; a third capacitor coupled between the control terminal of the fourth transistor and the first current path terminal of the third transistor; and a fourth capacitor coupled between the control terminal of the fourth transistor and the second current path terminal of the third transistor.

Example 23. The integrated circuit of one of examples 18 to 22, where the variable resistor is a first variable resistor, the variable capacitor is a first variable capacitor, and the integrated circuit includes: a second variable resistor having a first terminal and a second terminal coupled to the second current path terminal of the third transistor; a second variable capacitor having a first terminal coupled to the control terminal of the second transistor and a second terminal coupled to the first terminal of the second variable resistor; a third variable resistor having a first terminal and a second terminal coupled to the second current path terminal of the fourth transistor; and a third variable capacitor having a first terminal coupled to the control terminal of the first transistor and a second terminal coupled to the first terminal of the third variable resistor.

Example 24. The integrated circuit of one of examples 18 to 23, including: a third resistor having a first terminal and a second terminal coupled to the second current path terminal of the second transistor; a fifth capacitor having a first terminal and a second terminal coupled to the first terminal of the third resistor; a fourth resistor having a first terminal coupled to the second current path terminal of the first transistor and a second terminal coupled to the first terminal of the fifth capacitor; a fifth resistor having a first terminal coupled to the second current path terminal of the second transistor and a second terminal coupled to ground; and a sixth resistor having a first terminal coupled to the second current path terminal of the first transistor and a second terminal coupled to ground.

Example 25. A method including: causing, at a first time, a configurable output network of a digital signal attenuator (DSA) of a transceiver to operate in a first mode of operation; operating the DSA in the first mode of operation; causing, at a second time, the configurable output network of the DSA of the transceiver to operate in a second mode of operation; and operating the DSA in the second mode of operation.

Example 26. The method of example 25, where the first mode of operation is a wideband mode of operation and the second mode of operation is a narrowband mode of operation.

Example 27. The method of one of examples 25 or 26, where the first mode of operation includes operating the configurable output network of the DSA as a low-pass filter and the second mode of operation includes operating the configurable output network as a bandpass filter.

Example 28. The method of one of examples 25 to 27, where the configurable output network includes a first switch, a second switch, a first variable inductor, a second variable inductor, a variable resistor, and a variable capacitor, and the method includes: causing the configurable output network to operate in the first mode of operation by: opening the first switch and the second switch; setting respective inductances of the first variable inductor and the second variable inductor; and disabling the variable resistor and the variable capacitor; and causing the configurable output network to operate in the second mode of operation by: closing the first switch and the second switch; setting the respective inductances of the first variable inductor and the second variable inductor; setting a resistance of the variable resistor; and setting a capacitance of the variable capacitor.

Example 29. The method of one of examples 25 to 28, where the configurable output network includes a first switch, a second switch, a first variable inductor, a second variable inductor, a variable resistor, and a variable capacitor, and the method includes: causing the configurable output network to operate in the first mode of operation by: closing the first switch and the second switch; setting respective inductances of the first variable inductor and the second variable inductor; setting a resistance of the variable resistor; and setting a capacitance of the variable capacitor; and causing the configurable output network to operate in the second mode of operation by: opening the first switch and the second switch; setting the respective inductances of the first variable inductor and the second variable inductor; and disabling the variable resistor and the variable capacitor.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An electronic circuit comprising:
an amplifier having first and second outputs, first and second inputs, and first and second terminals;
a high pass filter coupled between the first and second terminals of the amplifier; and
a configurable output network coupled between the first and second outputs of the amplifier.

2. The electronic circuit of claim 1, wherein the amplifier comprises:
a first transistor having a control terminal coupled to the first input of the amplifier, a first current path terminal coupled to the first output of the amplifier, and a second current path terminal coupled to the first terminal of the amplifier;
a second transistor having a control terminal coupled to the second input of the amplifier, a first current path terminal coupled to the second output of the amplifier, and a second current path terminal coupled to the second terminal of the amplifier;
a third transistor having a first current path terminal coupled to the first output of the amplifier, and a second current path terminal coupled to the first current path terminal of the first transistor; and
a fourth transistor having a first current path terminal coupled to the second output of the amplifier, and a second current path terminal coupled to the first current path terminal of the second transistor.

3. The electronic circuit of claim 2, further comprising:
a first capacitor coupled between the control terminal of the third transistor and the first current path terminal of the fourth transistor;
a second capacitor coupled between the control terminal of the third transistor and the second current path terminal of the fourth transistor;
a third capacitor coupled between the control terminal of the fourth transistor and the first current path terminal of the third transistor; and
a fourth capacitor coupled between the control terminal of the fourth transistor and the second current path terminal of the third transistor.

4. The electronic circuit of claim 2, wherein the high pass filter comprises:
a first capacitor coupled between the first terminal of the amplifier and the second terminal of the amplifier;
a first resistor coupled between the first terminal of the amplifier and the first capacitor; and
a second resistor coupled between the second terminal of the amplifier and the first capacitor.

5. The electronic circuit of claim 2, further comprising:
a first resistor coupled between the first terminal of the amplifier and ground; and
a second resistor coupled between the second terminal of the amplifier and ground.

6. The electronic circuit of claim 2, further comprising a configurable input network having:
a first output coupled to the second current path terminal of the third transistor;
a second output coupled to the second current path terminal of the fourth transistor;
a third output coupled to the control terminal of the first transistor; and
a fourth output coupled to the control terminal of the second transistor.

7. The electronic circuit of claim 6, wherein the configurable input network comprises:
first and second inputs;
a first resistor coupled between the first input of the configurable input network and the second current path terminal of the third transistor;
a first capacitor coupled between the first input of the configurable input network and the control terminal of the second transistor;
a second resistor coupled between the second input of the configurable input network and the second current path terminal of the fourth transistor; and
a second capacitor coupled between the second input of the configurable input network and the control terminal of the first transistor.

8. The electronic circuit of claim 7, wherein each of the first and second resistors has a configurable resistance, and each of the first and second capacitors has a configurable capacitance.

9. The electronic circuit of claim 1, wherein the configurable output network comprises an inductor coupled between the first and second outputs of the amplifier.

10. The electronic circuit of claim 9, wherein the inductor comprises:
a first metal layer disposed above a semiconductor substrate;
a second metal layer disposed above the semiconductor substrate;
a third switch having a first terminal and a second terminal;
a first connector disposed in the first metal layer and coupled to the first terminal of the third switch;
a second connector disposed in the first metal layer and coupled to the second terminal of the third switch, the first connector and the second connector arranged in a first shape;
a fourth switch having a first terminal and a second terminal;
a third connector disposed in the first metal layer and coupled to the first terminal of the fourth switch;
a fourth connector disposed in the second metal layer and coupled to the third connector and the second terminal of the third switch; and
a fifth connector disposed in the first metal layer and coupled to the second terminal of the fourth switch and the first terminal of the third switch, the third connector and the fifth connector arranged in a second shape concentric with the first shape.

11. The electronic circuit of claim 9, wherein the inductor comprises:
a first metal layer disposed above a semiconductor substrate;
a second metal layer disposed above the semiconductor substrate;
a third switch having a first terminal and a second terminal;
a first connector disposed in the first metal layer and coupled to the first terminal of the third switch;
a second connector disposed in the first metal layer and coupled to the second terminal of the third switch, the first connector and the second connector arranged in a first shape;
a fourth switch having a first terminal and a second terminal;
a third connector disposed in the second metal layer and coupled to the first terminal of the fourth switch and the second terminal of the third switch; and
a fourth connector disposed in the second metal layer and coupled to the second terminal of the fourth switch and the first terminal of the third switch, the third connector and the fourth connector arranged in a second shape concentric with and substantially aligned to the first shape.

12. The electronic circuit of claim 9, wherein the configurable output network comprises:
a first resistor coupled between the first output of the amplifier and the inductor; and
a second resistor coupled between the second output of the amplifier and the inductor.

13. The electronic circuit of claim 12, wherein the configurable output network comprises:
a first switch coupled in parallel with the first resistor; and
a second switch coupled in parallel with the second resistor.

14. The electronic circuit of claim 1, wherein the configurable output network comprises:
a variable resistor coupled between the first and second outputs of the amplifier; and
a variable capacitor coupled between the first and second outputs of the amplifier.

15. The electronic circuit of claim 1, wherein the configurable output network includes:
a first variable inductor having a first terminal and a second terminal, the second terminal of the first variable inductor coupled to a supply terminal;
a first resistor having a first terminal coupled to the first output of the amplifier and a second terminal coupled to the first terminal of the first variable inductor;
a first switch coupled in parallel with the first resistor;
a second variable inductor having a first terminal and a second terminal, the second terminal of the second variable inductor coupled to the supply terminal;
a second resistor having a first terminal coupled to the second output of the amplifier and a second terminal coupled to the first terminal of the second variable inductor;
a second switch coupled in parallel with the second resistor;
a variable resistor coupled between the first and second outputs of the amplifier; and
a variable capacitor coupled between the first and second outputs of the amplifier.

16. The electronic circuit of claim 15, including control circuitry configured to:
in a first mode, close the first switch and second switches; and
in a second mode, open the first and second switches.

17. The electronic circuit of claim 6, wherein the configurable input network, the amplifier, the high pass filter, and the configurable output network form a digital signal attenuator (DSA) having first and second outputs and first and second inputs, the electronic circuit comprising:
a balun circuit having first and second outputs and an input;
a matching network having first and second outputs coupled to the first and second inputs of the DSA, respectively, and first and second inputs coupled to the first and second outputs of the balun circuit, respectively;
a sampling circuit having first and second outputs and first and second inputs coupled to the first and second outputs of the DSA, respectively; and
an analog-to-digital converter (ADC) having first and second inputs coupled to the first and second outputs of the sampling circuit, respectively.

18. An integrated circuit comprising:
a semiconductor substrate;
a first metal layer disposed above the semiconductor substrate;
a second metal layer disposed above the semiconductor substrate;
a first switch having a first terminal and a second terminal;
a first connector disposed in the first metal layer and coupled to the first terminal of the first switch;
a second connector disposed in the first metal layer and coupled to the second terminal of the first switch, the first connector and the second connector arranged in a first shape;
a second switch having a first terminal and a second terminal;
a third connector disposed in the second metal layer and coupled to the first terminal of the second switch and the second terminal of the first switch; and
a fourth connector disposed in the second metal layer and coupled to the second terminal of the second switch and the first terminal of the first switch, the third connector and the fourth connector arranged in a second shape concentric with and substantially aligned to the first shape.

19. The integrated circuit of claim 18, wherein the first switch, the first connector, the second connector, the second switch, the third connector, and the fourth connector form a first variable inductor or a second variable inductor, the at least one of the first variable inductor or the second variable inductor including:
a third switch having a first terminal and a second terminal, the first terminal coupled to the second connector;
a fifth connector disposed in the second metal layer and coupled to the second terminal of the third switch and the first connector;
a sixth connector disposed in the first metal layer and coupled to the first terminal of the third switch; and
a seventh connector disposed in the first metal layer and coupled to the second terminal of the third switch, the sixth connector and the seventh connector arranged in a third shape concentric with the first shape.

20. The integrated circuit of claim 19, wherein the at least one of the first variable inductor or the second variable inductor includes:
a fourth switch having a first terminal and a second terminal;
an eighth connector disposed in the second metal layer and coupled to the first terminal of the fourth switch and the second terminal of the second switch;
a ninth connector disposed in the first metal layer and coupled to the first terminal of the second switch; and
a tenth connector disposed in the second metal layer and coupled to the second terminal of the fourth switch and the ninth connector, the eighth connector and the tenth connector arranged in a fourth shape concentric with and substantially aligned to the third shape.

21. The integrated circuit of claim 18, the first switch, the first connector, the second connector, the second switch, the third connector, and the fourth connector form at least one of a first variable inductor or a second variable inductor, and the integrated circuit includes:
the first variable inductor, the first variable inductor having a first terminal and a second terminal coupled to a supply terminal;
a first resistor having a first terminal and a second terminal coupled to the first terminal of the first variable inductor;
a third switch having a first terminal coupled to the first terminal of the first resistor and a second terminal coupled to the first terminal of the first variable inductor;
the second variable inductor, the second variable inductor having a first terminal and a second terminal coupled to the supply terminal;
a second resistor having a first terminal and a second terminal coupled to the first terminal of the second variable inductor;
a fourth switch having a first terminal coupled to the first terminal of the second resistor and a second terminal coupled to the first terminal of the second variable inductor;
a variable resistor having a first terminal coupled to the first terminal of the first resistor and a second terminal coupled to the first terminal of the second resistor; and
a variable capacitor having a first terminal coupled to the first terminal of the first resistor and a second terminal coupled to the first terminal of the second resistor.

22. The integrated circuit of claim 21, including:
a first transistor having a control terminal, a first current path terminal, and a second current path terminal;
a second transistor having a control terminal, a first current path terminal, and a second current path terminal;
a third transistor having a control terminal, a first current path terminal, and a second terminal, the first terminal coupled to the first terminal of the first resistor;
a fourth transistor having a control terminal, a first current path terminal, and a second current path terminal, the first current path terminal coupled to the first terminal of the second resistor;
a first capacitor coupled between the control terminal of the third transistor and the first current path terminal of the fourth transistor;
a second capacitor coupled between the control terminal of the third transistor and the second current path terminal of the fourth transistor;
a third capacitor coupled between the control terminal of the fourth transistor and the first current path terminal of the third transistor; and
a fourth capacitor coupled between the control terminal of the fourth transistor and the second current path terminal of the third transistor.

23. The integrated circuit of claim 22, wherein the variable resistor is a first variable resistor, the variable capacitor is a first variable capacitor, and the integrated circuit includes:
a second variable resistor having a first terminal and a second terminal coupled to the second current path terminal of the third transistor;
a second variable capacitor having a first terminal coupled to the control terminal of the second transistor and a second terminal coupled to the first terminal of the second variable resistor;
a third variable resistor having a first terminal and a second terminal coupled to the second current path terminal of the fourth transistor; and
a third variable capacitor having a first terminal coupled to the control terminal of the first transistor and a second terminal coupled to the first terminal of the third variable resistor.

24. The integrated circuit of claim 23, including:
a third resistor having a first terminal and a second terminal coupled to the second current path terminal of the second transistor;
a fifth capacitor having a first terminal and a second terminal coupled to the first terminal of the third resistor;
a fourth resistor having a first terminal coupled to the second current path terminal of the first transistor and a second terminal coupled to the first terminal of the fifth capacitor;
a fifth resistor having a first terminal coupled to the second current path terminal of the second transistor and a second terminal coupled to ground; and
a sixth resistor having a first terminal coupled to the second current path terminal of the first transistor and a second terminal coupled to ground.
